(19) United States
(12) Patent Application Publication
(10) Pub. No.: US 2026/0090167 A1
(43) Pub. Date: Mar. 26, 2026

(54) Display Device

(71) Applicant: LG Display Co., Ltd., Seoul (KR)

(72) Inventors: SungJoon Min, Goyang-si, Gyeonggi-do (KR); Yeonjun Oh, Incheon (KR); Dojoong Kim, Seoul (KR); JunHyuk Song, Seoul (KR); Taehyun Kim, Uijeongbu-si, Gyeonggi-do (KR)

(21) Appl. No.: 19/271,114

(22) Filed: Jul. 16, 2025

(30) Foreign Application Priority Data
Sep. 25, 2024 (KR) 10-2024-0129673

(51) Int. Cl. H10H 29/49

(52) U.S. Cl. CPC H10H 29/49

(57) ABSTRACT

Provided is a display device. The display device includes a stretchable lower substrate a plurality of plate patterns which is disposed on the lower substrate to be spaced apart from each other a plurality of line patterns which is disposed between plate patterns adjacent in a first direction, among the plurality of plate patterns and between plate patterns adjacent in a second direction different from the first direction, among the plurality of plate patterns, on the lower substrate a plurality of connection lines which is disposed above each of the plurality of line patterns and a plurality of auxiliary patterns which is adjacent to the plurality of plate patterns in a diagonal direction between the first direction and the second direction, on the lower substrate.

### CROSS-REFERENCE TO RELATED APPLICATION

This application claims the priority of Republic of Korea Patent Application No. 10-2024-0129673 filed on Sep. 25, 2024, which is hereby incorporated by reference in its entirety.

### BACKGROUND

### Field

The present disclosure relates to a display device, and more particularly to a stretchable display device which may be stretched.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Recently, a display device which is manufactured by forming a display unit and a wiring line on a flexible substrate such as plastic which is a flexible material so as to be stretchable in a specific direction and changed in various forms is getting attention as a next generation display device.

### SUMMARY

An object to be achieved by the present disclosure is to provide a display device with improved shock resistance.

Another object to be achieved by the present disclosure is to provide a display device in which a damage of a connection line is suppressed.

Still another object to be achieved by the present disclosure is to provide a display device with an improved stretching reliability.

Objects of the present disclosure are not limited to the above-mentioned objects, and other objects, which are not mentioned above, can be clearly understood by those skilled in the art from the following description.

In order to achieve the above-described object, according to an embodiment of the present disclosure, a display device may include a stretchable lower substrate a plurality of plate patterns which is disposed on the lower substrate to be spaced apart from each other a plurality of line patterns which is disposed between plate patterns adjacent in a first direction, among the plurality of plate patterns and between plate patterns adjacent in a second direction different from the first direction, among the plurality of plate patterns, on the lower substrate a plurality of connection lines which is disposed above each of the plurality of line patterns and a plurality of auxiliary patterns which is adjacent to the plurality of plate patterns in a diagonal direction between the first direction and the second direction, on the lower substrate.

In order to achieve the above-described object, according to an embodiment of the present disclosure, a display device may include a stretchable lower substrate a plurality of plate patterns which is disposed on the lower substrate to be spaced apart from each other a plurality of line patterns which is disposed between plate patterns adjacent in a first direction, among the plurality of plate patterns and between plate patterns adjacent in a second direction different from the first direction, among the plurality of plate patterns, on the lower substrate; and a plurality of connection lines which is disposed above each of the plurality of line patterns, and a first groove which does not overlap the plurality of plate patterns and the plurality of line patterns is defined on the lower substrate.

In order to achieve the above-described object, according to an embodiment of the present disclosure, a display device may include a stretchable lower substrate on which a first groove is defined a stretchable upper substrate which is opposite to the lower substrate and defines a second groove overlapping the first groove and a display panel disposed between the lower substrate and the upper substrate.

Other detailed matters of the exemplary embodiments are included in the detailed description and the drawings.

According to the exemplary embodiments of the present disclosure, the display device may include a damper (or an internal empty space) formed by a first groove defined on a lower substrate, a second groove defined on an upper substrate, and a through-hole defined on a display panel. In this case, when a force (or shock) is applied to the display device from the outside, the force (or shock) applied from the outside is not directly transmitted to the display panel, but may be dispersed by gas (for example, air) in the damper.

Accordingly, the shock resistance of the display device may be improved and damage of various components included in the display device, for example, a connection line, caused by the external shock may be suppressed. Therefore, the stretching reliability of the display device may be improved.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a side view schematically illustrating a display device according to exemplary embodiments of the present disclosure;

FIG. 2 is a plan view illustrating a display device according to exemplary embodiments of the present disclosure;

FIG. 3 is a plan view illustrating an example of a lower substrate and an upper substrate included in a display device of FIG. 2 according to exemplary embodiments of the present disclosure;

FIG. 4 is an enlarged plan view illustrating an example of a part A of FIG. 2 according to exemplary embodiments of the present disclosure;

FIG. 5 is a cross-sectional view illustrating an example taken along the line III-III′ of FIG. 4 according to exemplary embodiments of the present disclosure;

FIG. 6 is a cross-sectional view illustrating an example taken along the line IV-IV′ of FIG. 4 according to exemplary embodiments of the present disclosure;

FIG. 7 is a view for explaining an example of a damper formed in a display device, by a lower substrate, an upper substrate, and a display panel included in a display device of FIG. 2 according to exemplary embodiments of the present disclosure;

FIGS. 8A and 8B are views for explaining an example that a shock is applied to a display device according to a comparative embodiment of the present disclosure;

FIGS. 9A and 9C are views for explaining an example that a shock is applied to a display device according to exemplary embodiments of the present disclosure;

FIGS. 10A to 10L are process charts illustrating a manufacturing method of a display device according to exemplary embodiments of the present disclosure;

FIG. 11 is an enlarged plan view illustrating another example of a part A of FIG. 2 according to exemplary embodiments of the present disclosure;

FIG. 12 is a plan view illustrating a display device according to exemplary embodiments of the present disclosure; and

FIG. 13 is a plan view illustrating an example of a lower substrate and an upper substrate included in a display device of FIG. 12 according to exemplary embodiments of the present disclosure.

### DETAILED DESCRIPTION

When the relation of a time sequential order is described using the terms such as “after”, “continuously to”, “next to”, and “before”, the order may not be continuous unless the terms are used with the term “immediately” or “directly”.

In describing components of the exemplary embodiment of the present disclosure, terminologies such as first, second, A, B, (a), (b), and the like may be used. These terminologies are used to distinguish a component from the other component, but a nature, an order, or the number of the components is not limited by the terminology. When a component is “linked”, “coupled”, or “connected” to another component, the component may be directly linked or connected to the other component. However, unless specifically stated otherwise, it should be understood that a third component may be interposed between the components which may be indirectly linked or connected.

It should be understood that “at least one” includes all combinations of one or more of associated components. For example, “at least one of first, second, and third components” means that not only a first, second, or third component, but also all combinations of two or more of first, second, and third components are included.

In the present specification, a “display device” may include a display device which includes a display panel and a driver for driving the display panel, in a narrow sense, such as a liquid crystal module (LCM), an organic light emitting module (OLED module), and a quantum dot (QD) module. Further, the “display device” may further include a set electronic apparatus or a set apparatus (or a set device) which is a complete product or a final product including an LCM, an OLED module, a QD module, etc., such as a notebook computer, a television, or a computer monitor, an automotive display device or equipment display device including another type of vehicle and a mobile electronic apparatus including a smart phone or an electronic pad.

Accordingly, the display device of the present disclosure may include not only a display device itself in a narrow sense such as an LCM, an OLED module, a QD module, etc., but also an applied product or a set apparatus which is a final consumer device including the LCD, the OLED module, the QD module, etc.

Further, in some cases, the LCM, the OLED module, or the QD module which is configured by a display panel and a driver may be represented as “a display device” in a narrow sense and an electronic device as a complete product including the LCM, the OLED module, and the QD module may be represented as a “set apparatus”. For example, the display device in the narrow sense includes a LCD display panel, an OLED display panel, or a quantum dot display panel and a source PCB which is a controller for driving the display panel. In contrast, the set apparatus may be a concept further including a set PCB which is a set controller which is electrically connected to the source PCB to control the entire set apparatus.

As a display panel used in the exemplary embodiment of the present disclosure, any type of display panel such as a liquid crystal display panel, OLED display panel, a quantum dot (QD) display panel, and an electroluminescent display panel may be used. The display panel of the present exemplary embodiment is not limited to a specific display panel in which a bezel is bent with a flexible substrate for the OLED display panel and a back plate support structure therebelow. Further, a display panel used for the display device according to the exemplary embodiment of the present disclosure is not limited to a shape or a size of the display panel.

For example, when the display panel is an OLED display panel, the display panel may include a plurality of gate lines, data lines, and pixels formed at intersecting areas of the gate lines and/or data lines. Further, the display panel may be configured to include an array including a thin film transistor which is an element to selectively apply a voltage to each pixel, a light emitting diode layer on the array, and an encapsulation substrate or an encapsulation layer, and the like disposed on the array so as to cover the light emitting diode layer. The encapsulation layer may protect the thin film transistor the light emitting diode layer, and the like from external impacts and may suppress the permeation of moisture or oxygen into the light emitting diode layer. Further, a layer formed on the array may include an inorganic light emitting layer, for example, a nano-sized material layer quantum dots, or the like.

The features of various exemplary embodiments of the present disclosure can be partially or entirely coupled to or combined with each other and can be interlocked and operated in technically various ways, and the exemplary embodiments can be carried out independently of or in association with each other.

Hereinafter, the present disclosure will be described with reference to the accompanying drawings and exemplary embodiments as follows. Scales of components illustrated in the accompanying drawings are different from the real scales for the purpose of description, so that the scales are not limited to those illustrated in the drawings.

Hereinafter, an exemplary embodiment of the present disclosure will be described in detail with reference to the drawings.

A display device according to exemplary embodiments of the present disclosure is a display device which is capable of displaying images even in a bent or extended state and is also referred to as a stretchable display device, a flexible display device and an extendable display device. As compared with the general display devices of the related art, the display device of the present disclosure has not only a high flexibility, but also stretchability. Therefore, the user may bend or extend a display device and a shape of a display device may be freely changed in accordance with manipulation of a user. For example, when the user pulls the display device by holding ends of the display device, the display device may be extended to the pulling direction of the user. Alternatively, when the user disposes the display device on an outer surface which is not flat, the display device may be disposed to be bent in accordance with the shape of the outer surface of the wall. Further, when a force applied by the user is removed, the display device may return to its original shape.

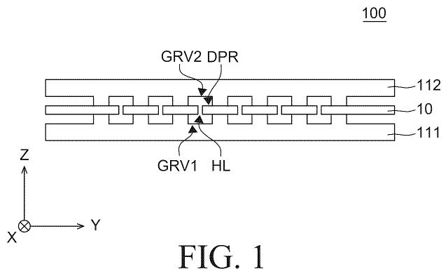

FIG. 1 is a side view schematically illustrating a display device according to exemplary embodiments of the present disclosure.

Referring to FIG. 1, a display device 100 according to exemplary embodiments of the present disclosure is stretchable in various directions on the planar surface. For example, the display device 100 may be stretchable along any one of a first direction X and a second direction Y which is different from the first direction X or may be two-dimensionally stretchable along the first direction X and the second direction Y.

To this end, the display device 100 according to the exemplary embodiments of the present disclosure may include a lower substrate 111, an upper substrate 112, a display panel 10 disposed between the lower substrate 111 and the upper substrate 112.

The lower substrate 111 supports various components of the display device 100 and the upper substrate 112 may cover various components of the display device 100.

In one exemplary embodiment, the lower substrate 111 and the upper substrate 112 which are flexible substrates may include an insulating material which is bendable or extendable. The lower substrate 111 may be a stretchable lower substrate. The upper substrate 112 may be a stretchable upper substrate

Moduli of elasticity of the lower substrate 111 and the upper substrate 112 may be several MPa to several hundreds of MPa. According to the exemplary embodiment, a ductile breaking rate of each of the lower substrate 111 and the upper substrate 112 may be 100% or higher. Here, the ductile breaking rate refers to a stretching rate at a timing when an object to be stretched is broken or cracked.

In one exemplary embodiment, a groove may be formed on each of the lower substrate 111 and the upper substrate 112. In the meantime, in the present specification, the groove may be defined as a recess or a dented portion.

For example, the lower substrate 111 includes a plurality of first grooves GRV1 formed on a planar surface (for example, a top surface) which is opposite to the upper substrate 112. The plurality of first grooves GRV1 may be formed by removing at least a part of the lower substrate 111 on a planar surface of the lower substrate 111 (for example, the top surface opposite to the upper substrate 112). For example, a width (for example, a thickness) of the lower substrate 111 along a third direction Z in an area in which the first groove GRV1 is defined may be smaller than a width (for example, a thickness) of the lower substrate 111 along the third direction Z in an area in which the first groove GRV1 is not defined.

Further, the upper substrate 112 may include a plurality of second grooves GRV2 formed on a planar surface (for example, a bottom surface) which is opposite to the lower substrate 111. The plurality of second grooves GRV2 may be formed by removing at least a part of the upper substrate 112 on a planar surface of the upper substrate 112 (for example, the bottom surface opposite to the lower substrate 111). For example, a width (for example, a thickness) of the upper substrate 112 along a third direction Z in an area in which the second groove GRV2 is defined may be smaller than a width (for example, a thickness) of the upper substrate 112 along the third direction Z in an area in which the second groove GRV2 is not defined.

In one exemplary embodiment, each of the plurality of first grooves GRV1 defined on the lower substrate 111 may be disposed so as to overlap each of the plurality of second grooves GRV2 defined on the upper substrate 112. According to the exemplary embodiment, the first groove GRV1 and the second groove GRV2 which overlap each other have the same shape and the same size, but are not limited thereto.

Accordingly, in the lower substrate 111 and the upper substrate 112, the plurality of grooves GRV1 and GRV2 which is disposed so as to overlap each other on opposite planar surfaces (for example, the top surface of the lower substrate 111 and/or the bottom surface of the upper substrate 112) is defined. Therefore, an internal empty space may be defined between the lower substrate 111 and the upper substrate 112 by the first groove GRV1 and the second groove GRV2 which are disposed so as to overlap each other. Here, the internal empty space may be defined as a damper (DPR, or a damper room), but the term is not limited thereto.

The display panel 10 may be disposed between the lower substrate 111 and the upper substrate 112. The display panel 10 includes a plurality of pixels and may display images through the plurality of pixels.

In one exemplary embodiment, the display panel 10 may include a plurality of through-holes HL. For example, an opening is formed in at least one insulating layer included in the display panel 10 to form the plurality of through-holes HL.

Each of the plurality of through-holes HL may be disposed so as to overlap the first groove GRV1 and the second groove GRV2 which are disposed so as to overlap each other. That is, the first groove GRV1, the second groove GRV2, and the through-hole HL are disposed so as to overlap each other so that a damper DPR may be formed (or defined) between the lower substrate 111 and the upper substrate 112, that is, in the display device 100, as an internal empty space.

According to the exemplary embodiment, the damper DPR (or the internal empty space) formed by the first groove GRV1, the second groove GRV2, and the through-hole HL may be filled with gas, for example, air. In this case, when a force (or a shock) is applied to the display device 100 from the outside, the force (or the shock) applied from the outside is not directly transmitted to the display panel 10, but may be dispersed by the air in the damper DPR. Accordingly, the shock resistance of the display panel 10 (or the display device 100) may be improved and damages of various components included in the display panel 10 (or the display device 100) caused by the external shock may be suppressed.

In the meantime, the exemplary embodiment of the present disclosure is not limited thereto and the damper DPR (or the internal empty space) formed by the first groove GRV1, the second groove GRV2, and the through-hole HL may be filled with various types of gas.

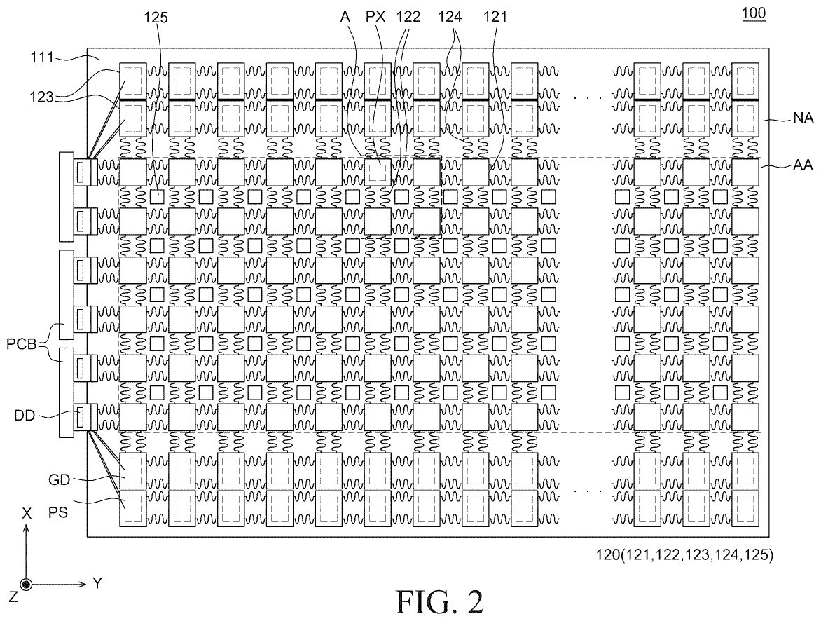

FIG. 2 is a plan view illustrating a display device according to exemplary embodiments of the present disclosure.

In the meantime, the display panel 10 which has been described with reference to FIG. 1 may refer to components other than the lower substrate 111 and the upper substrate 112, among the components of the display device 100 which will be described below. That is, in the present specification, all components disposed between the lower substrate 111 and the upper substrate 112, among components included in the display device 100, may be defined as the display panel 10.

Referring to FIGS. 1 and 2, a display device 100 according to exemplary embodiments of the present disclosure may include a lower substrate 111, an upper substrate 112, a pattern layer 120, a plurality of pixels PX, a gate driver GD, a data driver DD, and a power supply PS.

The lower substrate 111 supports the pattern layer 120 on which the pixel PX, the gate driver GD, and the power supply PS are formed and the upper substrate 112 may cover the pixel PX, the gate driver GD, and the power supply PS.

The lower substrate 111 may include an active area AA in which images are displayed and a non-active area NA excluding the active area AA. For example, on the active area AA, a plurality of pixels PX each including a display element and a circuit element is disposed and on the non-active area NA, a gate driver GD and a power supply PS for driving the plurality of pixels PX disposed in the active area AA may be disposed.

The pattern layer 120 may be disposed on the lower substrate 111.

In one exemplary embodiment, the pattern layer 120 may include a plurality of first plate patterns 121 and a plurality of first line patterns 122 disposed in the active area AA and a plurality of second plate patterns 123 and a plurality of second line patterns 124 disposed in the non-active area NA. For example, the plurality of first plate patterns 121 and the plurality of second plate patterns 123 are formed in the form of separate islands. The plurality of first line patterns 122 may be disposed between first plate patterns 121 which are adjacent to each other to connect the first plate patterns 121 which are adjacent to each other and the plurality of second line patterns 124 connects a first plate pattern 121 and a second plate pattern 123 which are adjacent to each other or a plurality of second plate patterns 123 which is adjacent to each other. A plurality of line patterns may be disposed between plate patterns adjacent in a first direction, among the plurality of plate patterns and between plate patterns adjacent in a second direction different from the first direction, among the plurality of plate patterns, on the lower substrate 111

The plurality of pixels PX are formed on the plurality of first plate patterns 121 and the gate driver GD and the power supply PS may be formed on the plurality of second plate patterns 123.

In the meantime, even though in FIG. 2, it is illustrated that the plurality of first plate patterns 121 and the plurality of second plate patterns 123 have a quadrangular shape, it is not limited thereto.

The plurality of first line patterns 122 and second line patterns 124 have a curved shape (for example, a sine wave shape), but are not limited thereto. For example, the plurality of first line patterns 122 and second line patterns 124 may extend in a zigzag pattern or may be formed with various shapes such as a shape extended by connecting a plurality of rhombus-shaped patterns at vertexes.

In one exemplary embodiment, the pattern layer 120 may further include a plurality of first auxiliary patterns 125 disposed in the active area AA.

The plurality of first auxiliary patterns 125 may be disposed in the form of islands which are spaced apart from each other. The plurality of first auxiliary patterns 125 may be individually separated. In FIG. 2, it is illustrated that the plurality of first auxiliary patterns 125 has a quadrangular shape, but is not limited thereto and the plurality of first auxiliary patterns 125 may be modified in various forms.

In one exemplary embodiment, each of the plurality of first auxiliary patterns 125 is disposed to be adjacent to the plurality of first plate patterns 121 in a direction different from the first direction X and the second direction Y. For example, each of the plurality of first auxiliary patterns 125 may be disposed to be adjacent to the plurality of first plate patterns 121 in a diagonal direction (for example, a third direction) between the first direction X and the second direction Y. Therefore, as illustrated in FIG. 2, each of the plurality of first auxiliary patterns 125 may be disposed between the first line patterns 122 which are adjacent in the first direction X and/or between the first line patterns 122 which are adjacent in the second direction Y.

In the meantime, as illustrated in FIG. 2, the plurality of first auxiliary patterns 125 are not connected to the line pattern, for example, the first line pattern 122 and the second line pattern 124, but may be spaced apart from each other, unlike the first plate pattern 121 and the second plate pattern 123.

In the meantime, even though in FIG. 2, it is illustrated that the plurality of first auxiliary patterns 125 are disposed in the active area AA, the exemplary embodiment is not limited thereto so that the plurality of first auxiliary patterns 125 may be disposed only in the non-active area NA or disposed in the active area AA and the non-active area NA, entirely.

In one exemplary embodiment, the plurality of first plate patterns 121, the plurality of first line patterns 122, the plurality of second plate patterns 123, the plurality of second line patterns 124, and the plurality of first auxiliary patterns 125 may be rigid patterns. That is, the plurality of first plate patterns 121, the plurality of first line patterns 122, the plurality of second plate patterns 123, the plurality of second line patterns 124, and the plurality of first auxiliary patterns 125 may be more rigid than the lower substrate 111 and the upper substrate 112. Accordingly, moduli of elasticity and a hardness of the plurality of first plate patterns 121, the plurality of first line patterns 122, the plurality of second plate patterns 123, the plurality of second line patterns 124, and the plurality of first auxiliary patterns 125 may be higher than a modulus of elasticity and a hardness of the lower substrate 111. For example, moduli of elasticity of the plurality of first plate patterns 121, the plurality of first line patterns 122, the plurality of second plate patterns 123, the plurality of second line patterns 124, and the plurality of first auxiliary patterns 125 may be 1000 times higher than the moduli of elasticity of the lower substrate 111 and the upper substrate 112, but it is not limited thereto.

The plurality of first plate patterns 121, the plurality of first line patterns 122, the plurality of second plate patterns 123, the plurality of second line patterns 124, and the plurality of first auxiliary patterns 125 may be formed of a plastic material having a lower flexibility than the lower substrate 111 and the upper substrate 112. For example, the plurality of first plate patterns 121, the plurality of first line patterns 122, the plurality of second plate patterns 123, the plurality of second line patterns 124, and the plurality of first auxiliary patterns 125 may include at least one material of polyimide (PI), polyacrylate, and polyacetate. At this time, the plurality of first plate patterns 121, the plurality of first line patterns 122, the plurality of second plate patterns 123, the plurality of second line patterns 124, and the plurality of first auxiliary patterns 125 may be formed of the same material, but is not limited thereto and may be formed of different materials. According to the exemplary embodiment, when the plurality of first plate patterns 121, the plurality of first line patterns 122, the plurality of second plate patterns 123, the plurality of second line patterns 124, and the plurality of first auxiliary patterns 125 are formed of the same material, the patterns may be integrally formed.

The gate driver GD may supply a gate signal to the plurality of pixels PX disposed in the active area AA. The gate driver GD includes a plurality of stages formed on the plurality of second plate patterns 123 and each stage of the gate driver GD may be electrically connected to each other by means of the plurality of gate connection lines. Accordingly, a gate signal output from any one of stages may be transmitted to the other stage. Each stage may sequentially supply the gate signal to the plurality of pixels PX connected to each stage.

The power supply PS is connected to the gate driver GD to supply a gate driving voltage and a gate clock voltage. Further, the power supply PS is connected to the plurality of pixels PX to supply a pixel driving voltage to each of the plurality of pixels PX.

The printed circuit board PCB includes a controller, such as an IC chip or a circuit unit and/or a memory or a processor to transmit a signal and a voltage for driving the display element from the controller to the display element. The printed circuit board PCB may include a stretching area and a non-stretching area to ensure stretchability. For example, in the non-stretching area, an IC chip, a circuit unit, a memory, and a processor are mounted and in the stretching area, wiring lines which are electrically connected to the IC chip, the circuit unit, the memory, and the processor may be disposed.

The data driver DD may supply a data voltage to the plurality of pixels PX disposed in the active area AA. The data driver DD may be configured as an IC chip so that it may also be referred to as a data integrated circuit D-IC.

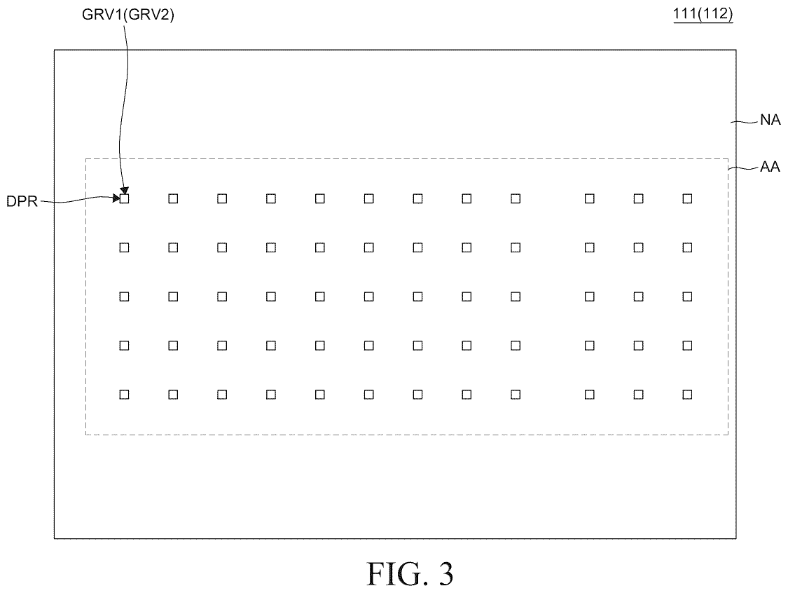

FIG. 3 is a plan view illustrating an example of a lower substrate and an upper substrate included in a display device of FIG. 2.

Referring to FIG. 3, a groove may be formed in each of the lower substrate 111 and the upper substrate 112. For example, as described with reference to FIG. 1, the lower substrate 111 includes a plurality of first grooves GRV1 formed on a planar surface (for example, a top surface) opposite to the upper substrate 112 and the upper substrate 112 includes a plurality of second grooves GRV2 formed on a planar surface (for example, a bottom surface) opposite to the lower substrate 111.

In one exemplary embodiment, each of the plurality of first grooves GRV1 defined in the lower substrate 111 may overlap each of the plurality of second grooves GRV2 defined in the upper substrate 112. For example, the plurality of first grooves GRV1 defined on the lower substrate 111 and the plurality of second grooves GRV2 defined on the upper substrate 112 may be formed in the same position on the planar surface.

Each of the plurality of first grooves GRV1 and each of the plurality of second grooves GRV2 may be disposed on the active area AA. For example, each of the plurality of first grooves GRV1 and each of the plurality of second grooves GRV2 may be disposed so as to overlap the plurality of first auxiliary patterns 125 included in the pattern layer 120. That is, each of the plurality of first grooves GRV1 and each of the plurality of second grooves GRV2 may be disposed so as not to overlap (e.g., non-overlapping) the plurality of first plate patterns 121 and the plurality of first line patterns 122 included in the pattern layer 120. Accordingly, the damper DPR defined by the first groove GRV1 and the second groove GRV2 may be formed so as to overlap the plurality of first auxiliary patterns 125. That is, the damper DPR may be formed in an area in which the plurality of first auxiliary patterns 125 is disposed.

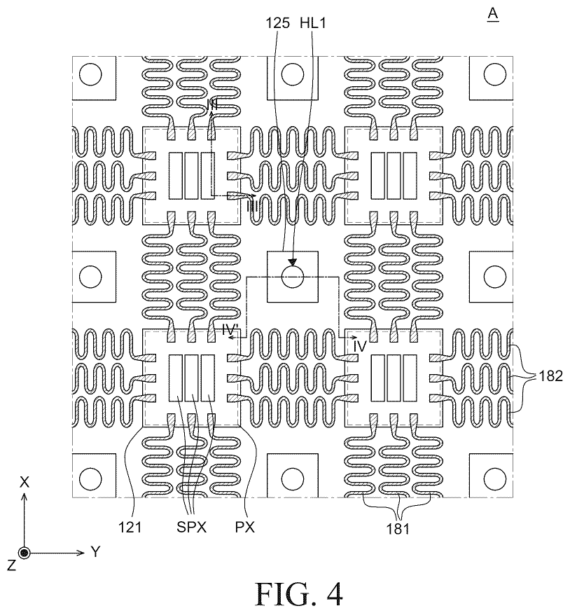

FIG. 4 is an enlarged plan view illustrating an example of a part A of FIG. 2 according to one embodiment.

Referring to FIGS. 2, 3, and 4, the plurality of first plate patterns 121 may be disposed on the active area AA of the lower substrate 111. The plurality of first plate patterns 121 are spaced apart from each other to be disposed on the lower substrate 111. For example, as illustrated in FIG. 2, the plurality of first plate patterns 121 may be disposed on the lower substrate 111 in a matrix, but is not limited thereto.

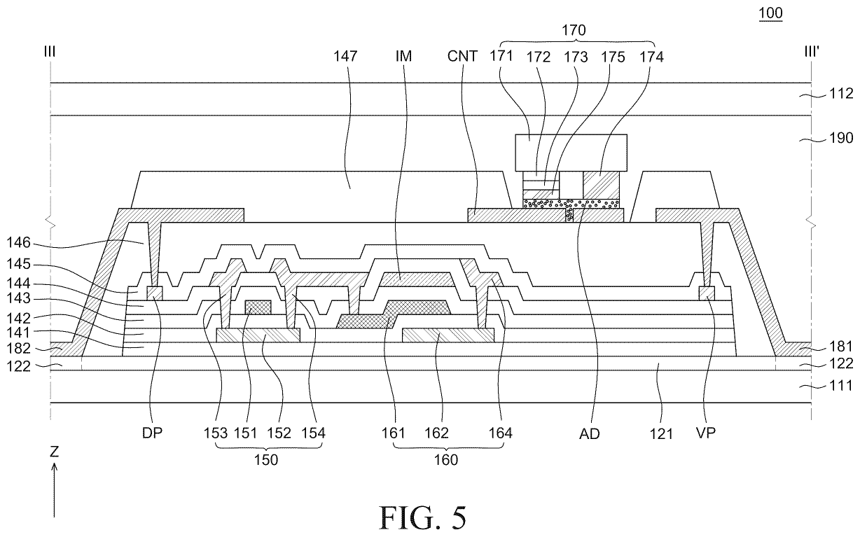

A pixel PX including the plurality of sub pixels SPX may be disposed in the first plate pattern 121. Each of the sub pixel SPX may include a display element (for example, an LED 170 of FIG. 5) and at least one transistor (for example, a driving transistor 160 and a switching transistor 150 of FIG. 5) for driving the display element.

The plurality of sub pixels SPX may include a red sub pixel, a green sub pixel, and a blue sub pixel, but is not limited thereto and colors of the plurality of sub pixels SPX may be modified to various colors as needed.

The plurality of sub pixels SPX may be connected to a plurality of connection lines 181 and 182. That is, the plurality of sub pixels SPX may be electrically connected to a first connection line 181 extending in the first direction X and a second connection line 182 extending in the second direction Y. A plurality of connection lines may be disposed above each of the plurality of line patterns

Further, the plurality of first auxiliary patterns 125 may be disposed on the active area AA of the lower substrate 111. The plurality of first auxiliary patterns 125 are spaced apart from each other and disposed on the lower substrate 111. For example, as illustrated in FIG. 2, the plurality of first auxiliary patterns 125 may be disposed on the lower substrate 111 in a matrix, but is not limited thereto.

In one exemplary embodiment, each of the plurality of first auxiliary patterns 125 is disposed to be adjacent to the plurality of first plate patterns 121 in a diagonal direction (or a third direction) between the first direction X and the second direction Y. Further, the plurality of first auxiliary patterns may be disposed between the first line patterns 122 adjacent in the first direction X and/or between the first line patterns 122 adjacent in the second direction Y.

Further, as illustrated in FIG. 4, the plurality of first auxiliary patterns 125 are not connected to the line pattern, for example, the first line pattern 122 and the second line pattern 124, but is spaced apart from each other, unlike the first plate pattern 121 and the second plate pattern 123.

In one exemplary embodiment, each of the plurality of first auxiliary patterns 125 may include a first through-hole HL1. For example, at least a part of each of the plurality of first auxiliary patterns 125 is removed to form a first through-hole HL1.

According to the exemplary embodiment, the first through-hole HL1 formed in each of the plurality of first auxiliary patterns 125 may be formed in the center portion of the first auxiliary pattern 125, but is not limited thereto and may be formed in various positions of the first auxiliary pattern 125.

The first through-hole HL1 included in the plurality of first auxiliary patterns 125 may be disposed so as to overlap the first groove GRV1 and the second groove GRV2 which are disposed so as to overlap each other. That is, the first groove GRV1, the second groove GRV2, and the first through-hole HL1 are disposed so as to overlap each other so that a damper DPR may be formed (or defined) between the lower substrate 111 and the upper substrate 112, that is, in the display device 100, as an internal empty space.

In the meantime, by doing this, the first through-hole HL1 included in each of the plurality of first auxiliary patterns 125 and the first groove GRV1 and the second groove GRV2 which overlap the first through-hole are disposed to be adjacent to the plurality of first plate patterns 121 in a diagonal direction (or a third direction) between the first direction X and the second direction Y on a planar surface. Further, the first through-hole HL1, the first groove GRV1, and the second groove GRV2 may be disposed between the first line patterns 122 adjacent in the first direction X and/or between the first line patterns 122 adjacent in the second direction Y.

In the meantime, even though in FIG. 4, it is illustrated that one first through-hole HL1 is formed in one first auxiliary pattern 125, this is just illustrative, and the number of first through-holes HL1 included in one first auxiliary pattern 125 is not limited thereto.

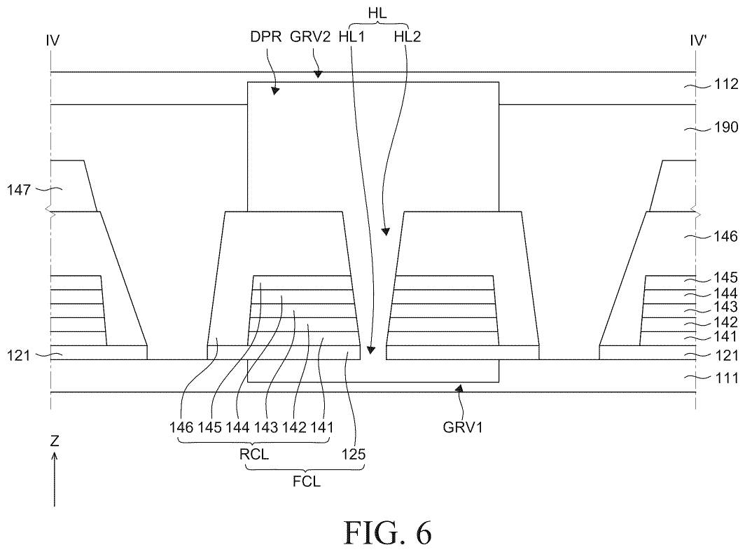

Hereinafter, a cross-sectional structure of the display device 100 in the active area AA will be described in more detail with reference to FIGS. 5 and 6.

FIG. 5 is a cross-sectional view illustrating an example taken along the line III-III′ of FIG. 4 according to one embodiment.

FIG. 6 is a cross-sectional view illustrating an example taken along the line IV-IV′ of FIG. 4 according to one embodiment.

First, referring to FIG. 5, a plurality of inorganic insulating layers may be disposed on the plurality of first plate patterns 121. For example, a plurality of inorganic insulating layers may include a buffer layer 141, a gate insulating layer 142, a first interlayer insulating layer 143, a second interlayer insulating layer 144, and a passivation layer 145. However, the exemplary embodiment of the present disclosure is not limited thereto and various inorganic insulating layers are additionally disposed on the plurality of first plate patterns 121. One or more of the buffer layer 141, the gate insulating layer 142, the first interlayer insulating layer 143, the second interlayer insulating layer 144, and the passivation layer 145 which are inorganic insulating layers may be omitted.

The buffer layer 141 may be disposed on the plurality of first plate patterns 121. The buffer layer 141 includes an insulating material and may be formed on the plurality of first plate patterns 121 to protect various components of the display device 100 from permeation of moisture (H₂O) and oxygen (O₂) from the outside of the lower substrate 111 and the plurality of first plate patterns 121. However, the buffer layer 141 may be omitted depending on a structure or a characteristic of the display device 100.

In one exemplary embodiment, the buffer layer 141 may be formed in an area where the lower substrate 111 overlaps the plurality of first plate patterns 121 and the plurality of second plate patterns 123. As described above, the buffer layer 141 may be formed of an inorganic material so that the buffer layer 141 may be easily cracked or damaged during a process of stretching the display device 100. Therefore, the buffer layer 141 is not formed in an area between the plurality of first plate patterns 121 and the plurality of second plate patterns 123. Instead, the buffer layer 141 is patterned to have a shape of the plurality of first plate patterns 121 and the plurality of second plate patterns 123 to be disposed only above the plurality of first plate patterns 121 and the plurality of second plate patterns 123. Therefore, in the display device 100 according to the exemplary embodiment of the present disclosure, the buffer layer 141 is formed only in an area overlapping the plurality of first plate patterns 121 and the plurality of second plate patterns 123 which are rigid patterns. Therefore, even though the display device 100 is bent or extended to be deformed, the damage of various components of the display device 100 may be suppressed.

A switching transistor 150 including a gate electrode 151, an active layer 152, a source electrode 153, and a drain electrode 154 and a driving transistor 160 including a gate electrode 161, an active layer 162, a source electrode and a drain electrode 164 may be disposed on the buffer layer 141.

The active layer 152 of the switching transistor 150 and the active layer 162 of the driving transistor 160 may be disposed on the buffer layer 141. For example, the active layer 152 of the switching transistor 150 and the active layer 162 of the driving transistor 160 may be formed of oxide semiconductor or may be formed of amorphous silicon (a-Si), polycrystalline silicon (poly-Si), or an organic semiconductor.

The gate insulating layer 142 may be disposed on the active layer 152 of the switching transistor 150 and the active layer 162 of the driving transistor 160. The gate insulating layer 142 includes an insulating material and electrically insulates the gate electrode 151 of the switching transistor 150 from the active layer 152 of the switching transistor 150 and electrically insulates the gate electrode 161 of the driving transistor 160 from the active layer 162 of the driving transistor 160.

The gate electrode 151 of the switching transistor 150 and the gate electrode 161 of the driving transistor 160 may be disposed on the gate insulating layer 142. The gate electrode 151 of the switching transistor 150 and the gate electrode 161 of the driving transistor 160 may be disposed on the gate insulating layer 142 to be spaced apart from each other. Further, the gate electrode 151 of the switching transistor 150 overlaps the active layer 152 of the switching transistor 150 and the gate electrode 161 of the driving transistor 160 may overlap the active layer 162 of the driving transistor 160.

The gate electrode 151 of the switching transistor 150 and the gate electrode 161 of the driving transistor 160 may include various metal materials.

The first interlayer insulating layer 143 may be disposed on the gate electrode 151 of the switching transistor 150 and the gate electrode 161 of the driving transistor 160. The first interlayer insulating layer 143 includes an insulating material and may insulate the gate electrode 161 of the driving transistor 160 from an intermediate metal layer IM.

The intermediate metal layer IM may be disposed on the first interlayer insulating layer 143. The intermediate metal layer IM may overlap the gate electrode 161 of the driving transistor 160. Therefore, a storage capacitor is formed in an overlapping area of the intermediate metal layer IM and the gate electrode 161 of the driving transistor 160. For example, the gate electrode 161 of the driving transistor 160, the first interlayer insulating layer 143, and the intermediate metal layer IM may form the storage capacitor. However, the placement area of the intermediate metal layer IM is not limited thereto and the intermediate metal layer IM overlaps the other electrode to form the storage capacitor in various forms.

The second interlayer insulating layer 144 may be disposed on the intermediate metal layer IM. The second interlayer insulating layer 144 includes an insulating material and may insulate the gate electrode 151 of the switching transistor 150 from the source electrode 153 and the drain electrode 154 of the switching transistor 150. Further, the second interlayer insulating layer 144 may insulate the intermediate metal layer IM from the source electrode and the drain electrode 164 of the driving transistor 160.

The source electrode 153 and the drain electrode 154 of the switching transistor 150 may be disposed on the second interlayer insulating layer 144. Further, the source electrode and the drain electrode 164 of the driving transistor 160 may be disposed on the second interlayer insulating layer 144. The source electrode 153 and the drain electrode 154 of the switching transistor 150 may be disposed on the same layer to be spaced apart from each other.

In the meantime, even though in FIG. 5, the source electrode of the driving transistor 160 is omitted, the source electrode of the driving transistor 160 may also be disposed to be spaced apart from the drain electrode 164 on the same layer. In the switching transistor 150, the source electrode 153 and the drain electrode 154 may be in contact with the active layer 152 to be electrically connected to the active layer 152. Further, in the driving transistor 160, the source electrode and the drain electrode 164 may be in contact with the active layer 162 to be electrically connected to the active layer 162. Further, the drain electrode 154 of the switching transistor 150 is in contact with the gate electrode 161 of the driving transistor 160 through a contact hole to be electrically connected to the gate electrode 161 of the driving transistor 160.

A gate pad and a data pad DP may be disposed on the second interlayer insulating layer 144.

Specifically, the gate pad may transmit a gate signal to the plurality of sub pixels SPX. The gate pad may be connected to the first connection line 181 through a contact hole. Further, the gate signal supplied from the first connection line 181 may be transmitted to the gate electrode 151 of the switching transistor 150 from the gate pad through a wiring line formed on the first plate pattern 121.

Further, the data pad DP may transmit a data voltage to the plurality of sub pixels SPX. The data pad DP may be connected to the second connection line 182 through a contact hole. Further, the data voltage supplied from the second connection line 182 may be transmitted to the source electrode 153 of the switching transistor 150 from the data pad DP through a wiring line formed on the first plate pattern 121.

Further, the voltage pad VP may transmit a low potential voltage to the plurality of sub pixels SPX. The voltage pad VP may be connected to the first connection line 181 through a contact hole. Further, the low potential voltage supplied from the first connection line 181 may be transmitted to the n-electrode (negative electrode) 174 of the LED 170 from the voltage pad VP through a wiring line formed on the first plate pattern 121.

The passivation layer 145 may be formed on the switching transistor 150 and the driving transistor 160. That is, the passivation layer 145 may be disposed to cover the switching transistor 150 and the driving transistor 160 to protect the switching transistor 150 and the driving transistor 160 from the permeation of moisture and oxygen. The passivation layer 145 may be formed of an inorganic material and configured by a single layer or a double layer, but is not limited thereto.

Further, the gate insulating layer 142, the first interlayer insulating layer 143, the second interlayer insulating layer 144, and the passivation layer 145 are patterned to be formed only in an area overlapping the plurality of first plate patterns 121. The gate insulating layer 142, the first interlayer insulating layer 143, the second interlayer insulating layer 144, and the passivation layer 145 may also be formed of the inorganic material, similar to the buffer layer 141. Therefore, the gate insulating layer 142, the first interlayer insulating layer 143, the second interlayer insulating layer 144, and the passivation layer 145 may also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of first plate patterns 121. However, the gate insulating layer 142, the first interlayer insulating layer 143, the second interlayer insulating layer 144, and the passivation layer 145 are patterned to have a shape of the plurality of first plate patterns 121 to be formed only above the plurality of first plate patterns 121.

The planarization layer 146 may be formed on the passivation layer 145. The planarization layer 146 may planarize upper portions of the switching transistor 150 and the driving transistor 160. The planarization layer 146 may be configured by a single layer or a plurality of layers and may be formed of an organic material.

Referring to FIG. 5, the planarization layer 146 may be disposed so as to cover top surfaces and side surfaces of the buffer layer 141, the gate insulating layer 142, the first interlayer insulating layer 143, the second interlayer insulating layer 144, and the passivation layer 145 on the plurality of first plate patterns 121. Further, the planarization layer 146 may be disposed so as to enclose the buffer layer 141, the gate insulating layer 142, the first interlayer insulating layer 143, the second interlayer insulating layer 144, and the passivation layer 145 together with the plurality of first plate patterns 121. Specifically, the planarization layer 146 may be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of first plate patterns 121. Accordingly, the planarization layer 146 may supplement a step on side surfaces of the buffer layer 141, the gate insulating layer 142, the first interlayer insulating layer 143, the second interlayer insulating layer 144, and the passivation layer 145. Further, the planarization layer 146 may enhance an adhesive strength of the connection lines 181 and 182 disposed on a side surface of the planarization layer 146.

Referring to FIG. 5, an inclination angle of the side surface of the planarization layer 146 may be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 may have a slope which is gentler than a slope formed by the side surface of the passivation layer 145, the side surface of the first interlayer insulating layer 143, the side surface of the second interlayer insulating layer 144, the side surface of the gate insulating layer 142, and the side surface of the buffer layer 141. Therefore, the connection lines 181 and 182 which are disposed to be in contact with the side surface of the planarization layer 146 are disposed with a gentle slope so that when the display device 100 is stretched, the stress generated in the connection lines 181 and 182 may be reduced. Further, the side surface of the planarization layer 146 has a relatively gentle slope so that the crack of the connection lines 181 and 182 or separation thereof from the side surface of the planarization layer 146 may be suppressed.

Referring to FIGS. 4 and 5, the connection lines 181 and 182 may electrically connect the pads on the plurality of first plate patterns 121. The connection lines 181 and 182 may be disposed on the plurality of first line patterns 122. Further, the connection lines 181 and 182 may extend onto the plurality of first plate patterns 121 to be electrically connected to the gate pad and the data pad DP on the plurality of first plate patterns 121. Further, the first line pattern 122 is not disposed in an area where the connection lines 181 and 182 are not disposed, among areas between the plurality of first plate patterns 121.

The connection lines 181 and 182 may include a first connection line 181 and a second connection line 182. The first connection line 181 and the second connection line 182 may be disposed between the plurality of first plate patterns 121. The first connection line 181 and the second connection line 182 may include a metal material.

To be more specific, the first connection line 181 refers to a wiring line extending in a first direction X between the plurality of first plate patterns 121, among the connection lines 181 and 182. The second connection line 182 may refer to a wiring line extending in a second direction Y between the plurality of first plate patterns 121, among the connection lines 181 and 182.

In the meantime, in the case of a general display device, various wiring lines such as a plurality of gate lines and a plurality of data lines extend between the plurality of sub pixels with a linear shape and the plurality of sub pixels is connected to one signal line. Therefore, in the general display device, various wiring lines, such as a gate line, a data line, a high potential voltage line, and a reference voltage line, extend from one side to the other side of the organic light emitting display device without being disconnected on the substrate.

In contrast, in the display device 100 according to the exemplary embodiment of the present disclosure, various wiring lines, such as a gate line, a data line, a high potential voltage line, a reference voltage line, or an initialization voltage line having a straight line shape which are considered to be used for the general display device, may be disposed only on the plurality of first plate patterns 121 and the plurality of second plate patterns 123. That is, in the display device 100 according to the exemplary embodiment of the present disclosure, a linear wiring line may be disposed only on the plurality of first plate patterns 121 and the plurality of second plate patterns 123.

In the display device 100 according to the exemplary embodiment of the present disclosure, the pads on the two adjacent first plate patterns 121 may be connected by the connection lines 181 and 182. Accordingly, the connection lines 181 and 182 may electrically connect the gate pads or the data pads DP on two adjacent first plate patterns 121. Accordingly, the display device 100 according to the exemplary embodiment of the present disclosure may include a plurality of connection lines 181 and 182 which electrically connects various wiring lines, such as a gate line, a data line, a high potential voltage line, and a reference voltage line, between the plurality of first plate patterns 121. For example, the gate line may be disposed on the plurality of first plate patterns 121 disposed to be adjacent to each other in the first direction X and the gate pad may be disposed on both ends of the gate line. In this case, the plurality of gate pads on the plurality of first plate patterns 121 adjacent to each other in the first direction X may be connected to each other by the first connection line 181 which serves as a gate line. Therefore, the gate line disposed on the plurality of first plate patterns 121 and the first connection line 181 disposed on the first line pattern 122 may serve as one gate line. The above-described gate line may be referred to as a scan signal line. Further, wiring lines which extend in the first direction X, among all various wiring lines which may be included in the display device 100, such as an emission signal line, a low potential voltage line, and a high potential voltage line, may also be electrically connected by the first connection line 181, as described above.

Referring to FIGS. 4 to 5, the first connection lines 181 may connect the gate pads on two first plate patterns 121 which are disposed side by side, among the gate pads on the plurality of first plate patterns 121 disposed to be adjacent in the first direction X. The first connection line 181 may serve as a gate line, an emission signal line, a high potential voltage line, or a low potential voltage line, but is not limited thereto. The gate pads on the plurality of first plate patterns 121 disposed in the first direction X may be connected by the first connection line 181 serving as a gate line and transmit one gate voltage.

Further, referring to FIGS. 4 and 5, the second connection line 182 may connect the data pads DP on two first plate patterns 121 which are disposed side by side, among the data pads DP on the plurality of first plate patterns 121 disposed to be adjacent in the second direction Y. The second connection line 182 may serve as a data line, a high potential voltage line, a low potential voltage line, or a reference voltage line, but is not limited thereto. The line data pads DP on the plurality of first plate patterns 121 disposed in the second direction Y may be connected by the plurality of second connection lines 182 serving as a data line and transmit one data voltage.

As illustrated in FIG. 5, the first connection line 181 may be disposed to be in contact with a top surface and a side surface of the planarization layer 146 disposed on the first plate pattern 121. Further, the first connection line 181 may be formed to extend onto the top surface of the first line pattern 122. Further, the second connection line 182 may be disposed to be in contact with a top surface and a side surface of the planarization layer 146 disposed on the first plate pattern 121. Further, the second connection line 182 may be formed to extend onto the top surface of the first line pattern 122.

However, there is no need to dispose a rigid pattern in an area where the first connection line 181 and the second connection line 182 are not disposed. Therefore, the first line pattern 122 which is a rigid pattern is not disposed below the first connection line 181 and the second connection line 182.

In the meantime, referring to FIG. 5, a bank 147 may be formed on the connection pad CNT, the connection lines 181 and 182, and the planarization layer 146. The bank 147 includes an insulating material and may divide adjacent sub pixels SPX. The bank 147 may be disposed so as to cover at least a part of the connection lines 181 and 182 and the planarization layer 146. Further, even though in FIG. 5, it is illustrated that a height of the bank 147 is lower than a height of the LED 170, the present disclosure is not limited thereto and the height of the bank 147 may be equal to the height of the LED 170.

Referring to FIG. 5, the LED 170 may be disposed on the connection pad CNT and the first connection line 181. The LED 170 may include an n-type layer 171, an active layer 172, a p-type layer 173, an n-electrode 174, and a p-electrode 175. The LED 170 of the display device 100 according to the exemplary embodiment of the present disclosure may have a flip-chip structure in which the n-electrode 174 and the p-electrode (positive electrode) 175 are formed on one surface, but is not limited thereto.

The n-type layer 171 includes an n-type impurity and may be disposed on a separate base substrate which is formed of a material which is capable of emitting light.

The active layer 172 may be disposed on the n-type layer 171. The active layer 172 may correspond to an emission layer which emits light in the LED 170. The p-type layer 173 including a p-type impurity may be disposed on the active layer 172.

As described above, the LED 170 according to the exemplary embodiment of the present disclosure may be manufactured by sequentially laminating the n-type layer 171, the active layer 172, and the p-type layer 173, and then etching a predetermined part to form the n-electrode 174 and the p-electrode 175. In this case, the predetermined part which is a space for separating the n-electrode 174 and the p-electrode 175 from each other may be etched to expose a part of the n-type layer 171. In other words, the surfaces of the LED 170 on which the n-electrode 174 and the p-electrode 175 are disposed are not flat surfaces, but have different heights.

As described above, the n-electrode 174 is disposed in the etched area and may be formed of a conductive material. Further, the p-electrode 175 is disposed in an area which is not etched and may also be formed of a conductive material. For example, the n-electrode 174 is disposed on the n-type layer 171 which is exposed by the etching process and the p-electrode 175 may be disposed on the p-type layer 173. The p-electrode 175 may be formed of the same material as the n-electrode 174.

An adhesive layer AD is disposed on top surfaces of the connection pad CNT and the first connection line 181 and between the connection pad CNT and the first connection line 181 so that the LED 170 may be adhered onto the connection pad CNT and the first connection line 181. At this time, the n-electrode 174 is disposed on the first connection line 181 and the p-electrode 175 may be disposed on the connection pad CNT.

The adhesive layer AD may be a conductive adhesive layer in which conductive balls are dispersed in an insulating base member. Therefore, when heat or a pressure is applied to the adhesive layer AD, the conductive balls are electrically connected in a portion applied with the heat or pressure to have a conductive property and an area which is not pressurized may have an insulation property. For example, the n-electrode 174 is electrically connected to the first connection line 181 by means of the adhesive layer AD and the p-electrode 175 may be electrically connected to the connection pad CNT by means of the adhesive layer AD. After applying the adhesive layer AD onto the top surface of the first connection line 181 and the connection pad CNT by an inkjet method, the LED 170 is transferred onto the adhesive layer AD and is pressurized and heated. By doing this, the connection pad CNT is electrically connected to the p-electrode 175 and the first connection line 181 may be electrically connected to the n-electrode 174. However, the remaining part of the adhesive layer AD excluding a part of the adhesive layer AD disposed between the n-electrode 174 and the first connection pad 181 and a part of the adhesive layer AD disposed between the p-electrode 175 and the connection pad CNT has an insulation property. In the meantime, the adhesive layer AD may be divided to be disposed on the connection pad CNT and the first connection line 181, respectively.

Further, the connection pad CNT is electrically connected to the drain electrode 164 of the driving transistor 160 to be applied with a driving voltage from the driving transistor 160 to drive the LED 170. Even though in FIG. 5, it is illustrated that the connection pad CNT is not in direct contact with the drain electrode 164 of the driving transistor 160, but is in indirect connection therewith, the present disclosure is not limited thereto. Therefore, the connection pad CNT and the drain electrode 164 of the driving transistor 160 may be in direct contact with each other. Further, a low potential driving voltage may be applied to the first connection line 181 to drive the LED 170. Therefore, when the display device 100 is turned on, different voltage levels applied to the connection pad CNT and the first connection line 181 are transmitted to the n-electrode 174 and the p-electrode 175 so that the LED 170 may emit light.

The upper substrate 112 is a substrate which supports various components disposed below the upper substrate 112. Specifically, the upper substrate 112 is formed by coating a material which configures the upper substrate 112 on the lower substrate 111 and the first plate pattern 121 and then hardening the material to be disposed to be in contact with the lower substrate 111, the first plate pattern 121, the first line pattern 122, and the connection lines 181 and 182.

In the meantime, even though not illustrated in FIG. 5, a polarization layer may be disposed on the upper substrate 112. The polarization layer may function to polarize light incident from the outside of the display device 100 to reduce the external light reflection. Further, an optical film other than the polarization layer may be disposed on the upper substrate 112.

Further, the filling layer 190 may be disposed on the entire surface of the lower substrate 111 to be filled between the components disposed on the upper substrate 112 and the lower substrate 111. The filling layer 190 may be configured by a curable adhesive. Specifically, the material which configures the filling layer 190 is coated on the entire surface of the lower substrate 111 and then is cured so that the filling layer 190 may be disposed between the components disposed on the upper substrate 112 and the lower substrate 111. For example, the filling layer 190 may be an optically clear adhesive (OCA) and may be configured by an acrylic-based adhesive, a silicon-based adhesive, and a urethane-based adhesive.

Referring to FIG. 6, the lower substrate 111 includes the plurality of first grooves GRV1 and the upper substrate 112 may include the plurality of second grooves GRV2. For example, the plurality of first grooves GRV1 are formed by removing at least a part of the lower substrate 111 on a planar surface (for example, a top surface opposite to the upper substrate 112) of the lower substrate 111. The plurality of second grooves GRV2 may be formed by removing at least a part of the upper substrate 112 on a planar surface (for example, a bottom surface opposite to the lower substrate 111) of the upper substrate 112.

The plurality of first auxiliary patterns 125 may be disposed on the lower substrate 111. For example, the plurality of first auxiliary patterns 125 may be disposed so as to overlap the first groove GRV1 of the lower substrate 111.

Further, as illustrated in FIG. 6, a width of each of the plurality of first auxiliary patterns 125, for example, each of a width of each of the plurality of first auxiliary patterns 125 along the first direction X and a width of each of the plurality of first auxiliary patterns 125 along the second direction Y may be larger than a width of the first groove GRV1. Accordingly, each of the plurality of first auxiliary patterns 125 is not located in the first groove GRV1 of the lower substrate 111 and the bottom surface of the first auxiliary pattern 125 may be disposed to be spaced apart from the planar surface of the lower substrate 111 in which the first groove GRV1 is defined. For example, an end of the bottom surface of each of the plurality of first auxiliary patterns 125 is disposed to be in contact with a planar surface of a part of the lower substrate 111 in which the first groove GRV1 is not defined. The remaining part of the bottom surface of each of the plurality of first auxiliary patterns 125 may be disposed to be spaced apart from a planar surface of a part of the lower substrate 111 in which the first groove GRV1 is defined.

In one exemplary embodiment, each of the plurality of first auxiliary patterns 125 may include a first through-hole HL1. For example, at least a part of each of the plurality of first auxiliary patterns 125 is removed to form a first through-hole HL1. According to the exemplary embodiment, the first through-hole HL1 formed in each of the plurality of first auxiliary patterns 125 may be formed in the center portion of the first auxiliary pattern 125, but is not limited thereto.

A reinforcement layer RCL including at least one insulating layer, for example, a plurality of inorganic insulating layers may be disposed above each of the plurality of first auxiliary patterns 125. For example, the reinforcement layer RCL may also be formed on the plurality of first auxiliary patterns 125 by patterning the same inorganic insulating layer as the plurality of inorganic insulating layers disposed on the plurality of first plate patterns 121. For example, the reinforcement layer RCL may include a buffer layer 141, a gate insulating layer 142, a first interlayer insulating layer 143, a second interlayer insulating layer 144, a passivation layer 145, and a planarization layer 146.

According to the exemplary embodiment, during the process of manufacturing the buffer layer 141, the gate insulating layer 142, the first interlayer insulating layer 143, the second interlayer insulating layer 144, the passivation layer 145, and the planarization layer 146, in order to form the buffer layer 141, the gate insulating layer 142, the first interlayer insulating layer 143, the second interlayer insulating layer 144, the passivation layer 145, and the planarization layer 146 also on the plurality of first auxiliary patterns 125, an inorganic material for forming the buffer layer 141, the gate insulating layer 142, the first interlayer insulating layer 143, the second interlayer insulating layer 144, the passivation layer 145, and the planarization layer 146 is etched in a part in which the plurality of first plate patterns 121 and the plurality of first auxiliary patterns 125 are not disposed to form the reinforcement layer RCL.

In one exemplary embodiment, the reinforcement layer RCL may include a second through-hole HL2. For example, the plurality of inorganic insulating layers included in the reinforcement layer RCL, for example, at least a part of each of the buffer layer 141, the gate insulating layer 142, the first interlayer insulating layer 143, the second interlayer insulating layer 144, the passivation layer 145, and the planarization layer 146 is removed to form the second through-hole HL2.

According to the exemplary embodiment, the second through-hole HL2 formed in the reinforcement layer RCL may be formed in the center portion of the reinforcement layer RCL, but is not limited thereto and may be formed in various positions.

Further, the second through-hole HL2 formed in the reinforcement layer RCL may overlap the first through-hole HL1 formed in the first auxiliary pattern 125. Accordingly, the first through-hole HL1 and the second through-hole HL2 overlapping the first through-hole may configure the plurality of through-holes HL of the display panel 10 which has been described with reference to FIG. 1. According to the exemplary embodiment, the first auxiliary pattern 125 including the first through-hole HL1 and the reinforcement layer RCL which is disposed on the first auxiliary pattern 125 and has the second through-hole HL2 may be defined as a flow rate control layer FCL. That is, the through-hole HL including the first through-hole HL1 and the second through-hole HL2 may be defined on the flow rate control layer FCL.

In one exemplary embodiment, the through-hole HL, for example, the first through-hole HL1 and the second through-hole HL2 may be disposed so as to overlap the first groove GRV1 and the second groove GRV2 which overlap each other. That is, the first groove GRV1, the second groove GRV2, the first through-hole HL1, and the second through-hole HL2 may be disposed so as to overlap each other so that a damper DPR may be formed (or defined) between the lower substrate 111 and the upper substrate 112.

According to the exemplary embodiment, as described above, the damper DPR (or the internal empty space) formed by the first groove GRV1, the second groove GRV2, the first through-hole HL1, and the second through-hole HL2 may be filled with gas, for example, air. In this case, when a force (or a shock) is applied to the display device 100 from the outside, the force (or the shock) applied from the outside is not directly transmitted to the display device 100, but may be dispersed by the air in the damper DPR. Accordingly, the shock resistance of the display device 100 is improved and damages of various components included in the display device 100, for example, connection lines 181 and 182 formed on the line pattern, caused by the external shock may be suppressed. Therefore, the stretching reliability of the display device 100 may be improved.

In the meantime, the exemplary embodiment of the present disclosure is not limited thereto and the damper DPR (or the internal empty space) formed by the first groove GRV1, the second groove GRV2, the first through-hole HL1, and the second through-hole HL2 may be filled with various types of gas.

According to the exemplary embodiment, a width of each of the first groove GRV1 and the second groove GRV2 may be larger than a width of the through-hole HL, for example, a width of each of the first through-hole HL1 and the second through-hole HL2.

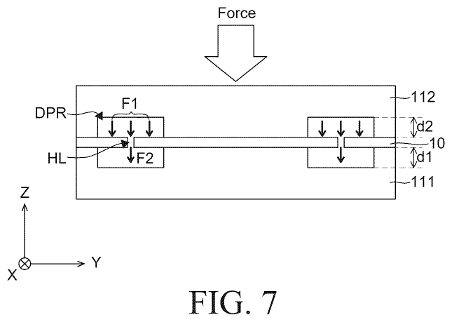

FIG. 7 is a view for explaining an example of a damper formed in a display device, by a lower substrate, an upper substrate, and a display panel included in a display device of FIG. 2.

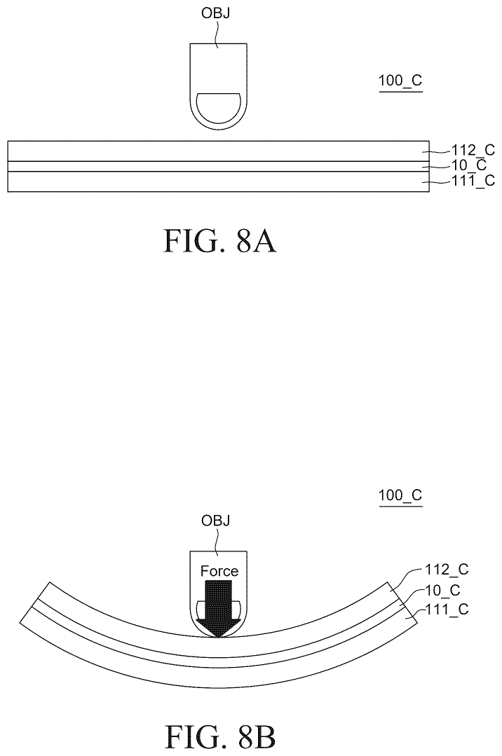

FIGS. 8A and 8B are views for explaining an example that a shock is applied to a display device according to a comparative embodiment of the present disclosure.

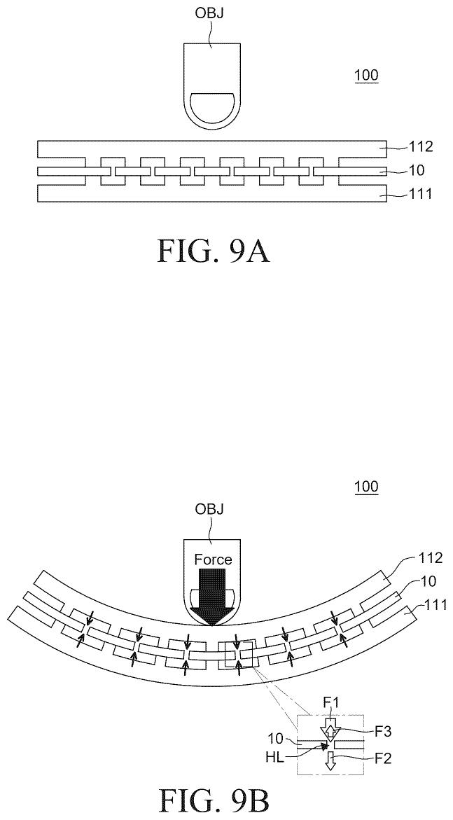

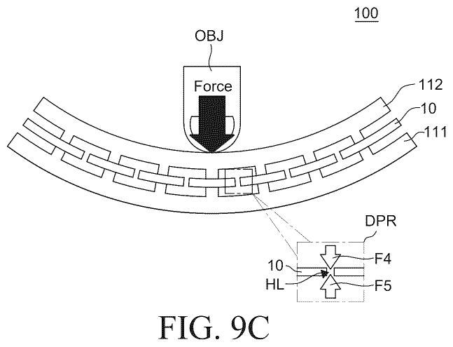

FIGS. 9A to 9C are views for explaining an example that a shock is applied to a display device according to exemplary embodiments of the present disclosure.

In the meantime, in FIGS. 8A and 8B, an example that an external shock is applied to a display device 100_C according to a comparative embodiment of the present disclosure in which a damper is not formed in the display device 100_C is illustrated. In FIGS. 9A to 9C, an example that an external shock is applied to a display device 100 according to an exemplary embodiment of the present disclosure in which a damper is formed in the display device 100 is illustrated.

First, referring to FIG. 7, as described above, the lower substrate 111 includes the first groove GRV1 and the upper substrate 112 includes the second groove GRV2 and the through-hole HL of the display panel 10 may be formed so as to overlap the first groove GRV1 and the second groove GRV2. Accordingly, an internal empty space, that is, the damper DPR may be formed in the display device 100.

Here, when a force is applied to the display device 100 from the outside, in the damper DPR in which a second groove GRV2 of a substrate located on a side surface to which the force is applied, for example, the upper substrate 112, is located, a first force F1 according to the air pressure may be generated in the same direction as the direction of the force applied from the outside. At this time, as described above, the width of the through-hole HL is smaller than the width of each of the first groove GRV1 and the second groove GRV2 so that the flow rate of the air is instantaneously controlled (for example, reduced) in the through-hole HL. Therefore, a second force F2 which is generated according to the air pressure in the damper DPR in which the first groove GRV1 of the lower substrate 111 is located may be smaller than the first force F1. For example, the flow rate of the air is instantaneously controlled (for example, reduced) in the through-hole HL so that a resistance force (for example, a force according to air resistance) is generated in an opposite direction to the direction in which the first force F1 is applied. Therefore, the second force F2 which is generated according to the air pressure in the damper DPR in which the first groove GRV1 of the lower substrate 111 is located may be smaller than the first force F1. The resistance force according to the air flow rate control acts in an opposite direction to the force which is applied from the outside so that damages of various components included in the display panel 10 caused by the external shocks may be suppressed.

To be more specific, referring to FIGS. 8A and 8B, when the force is applied along an object OBJ from the outside of the display device 100_C according to the comparative embodiment of the present disclosure, in the display device 100_C, a separate internal empty space is not formed. Therefore, the force applied from the outside may be transmitted to a lower substrate 111_C, an upper substrate 112_C, and a display panel 10_C as it is. Accordingly, various components included in the display panel 10_C may be damaged by the shocks which are applied from the outside. For example, the connection lines included in the display device 100_C may be damaged by the external shocks.

In contrast, referring to FIGS. 9A and 9B, when a force is applied along the object OBJ from the outside of the display device 100 according to the exemplary embodiments of the present disclosure, as described above with reference to FIG. 7, in the damper DPR in which a second groove GRV2 of a substrate located on a side surface to which the force is applied, for example, the upper substrate 112, is located, a first force F1 according to the air pressure is generated in the same direction as the direction of the force applied from the outside. The flow rate of the air is instantaneously controlled (for example, reduced) in the through-hole HL so that the second force F2 which is generated according to the air pressure in the damper DPR in which the first groove GRV1 of the lower substrate 111 is located may be smaller than the first force F1. For example, the flow rate of the air is instantaneously controlled (for example, reduced) in the through-hole HL so that a third force F3, for example, a force according to air resistance is generated in an opposite direction to the direction in which the first force F1 is applied. Therefore, the second force F2 which is generated according to the air pressure in the damper DPR in which the first groove GRV1 of the lower substrate 111 is located may be smaller than the first force F1. The third force F3 according to the air flow rate control acts in an opposite direction to the force which is applied from the outside so that damages of various components included in the display panel 10 caused by the external shocks may be suppressed.

In the meantime, when the force applied along the object OBJ from the outside is constantly maintained, as illustrated in FIG. 9C, a fourth force F4 acting in a portion of the damper DPR in which the second groove GRV2 is formed and a fifth force F5 acting in a portion in which the first groove GRV1 is formed are in equilibrium. Therefore, the display device 100 may stably maintain the modified state.

In the meantime, referring to FIG. 7, according to the exemplary embodiment, a first interval d1 between the display panel 10 and the lower substrate 111 in which the first groove GRV1 is defined and a second interval d2 between the display panel 10 and the upper substrate 112 in which the second groove GRV2 is defined may be equal. For example, the first interval d1 and the second interval d2 are 100 μm, but are not limited thereto and the first interval d1 and the second interval d2 may be determined according to how much the air flow rate is controlled.

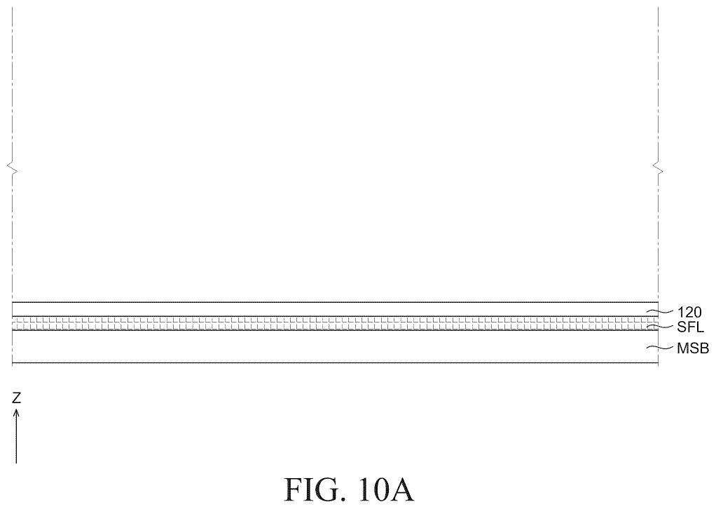

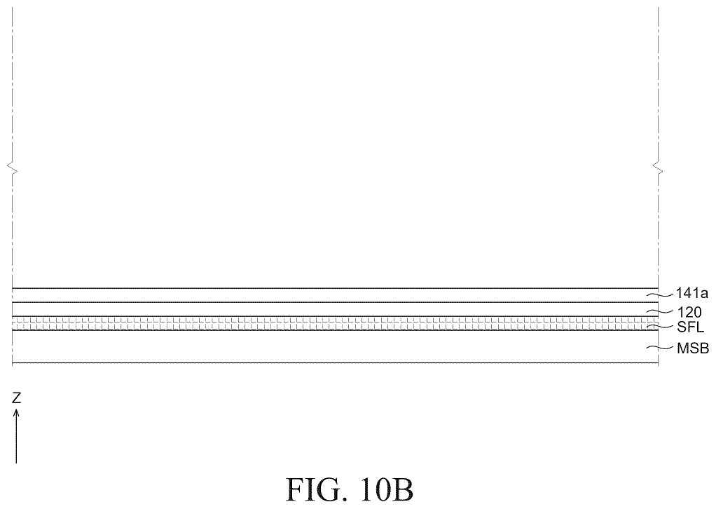

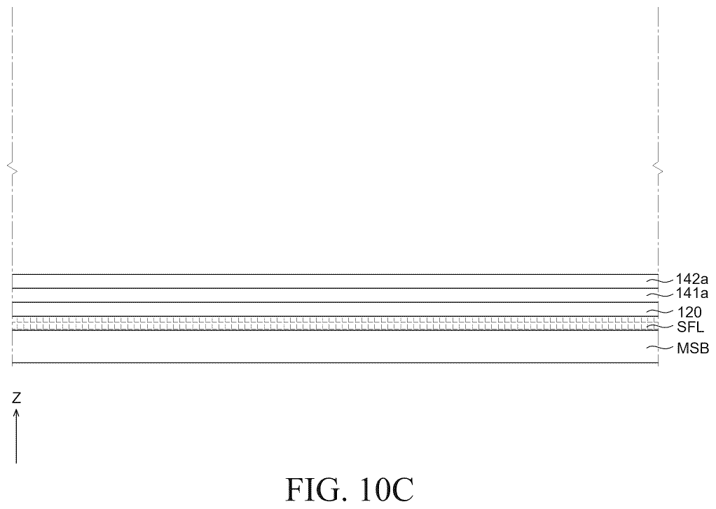

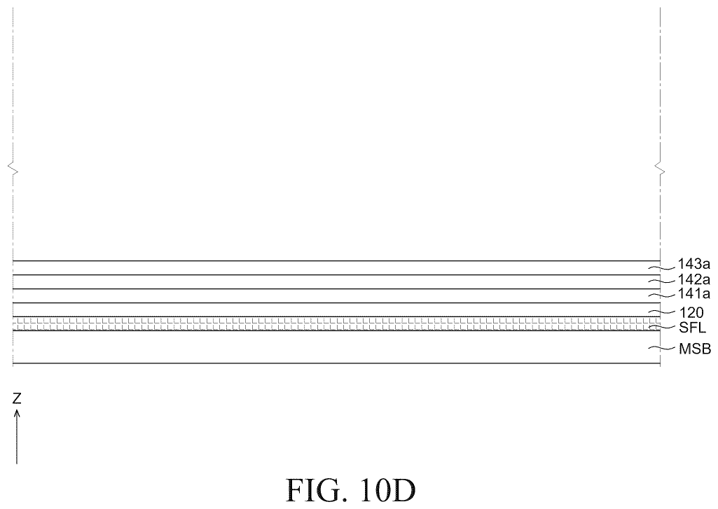

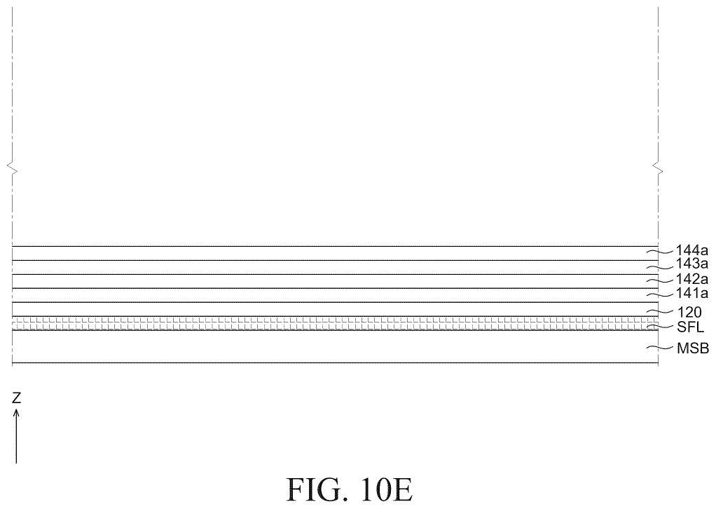

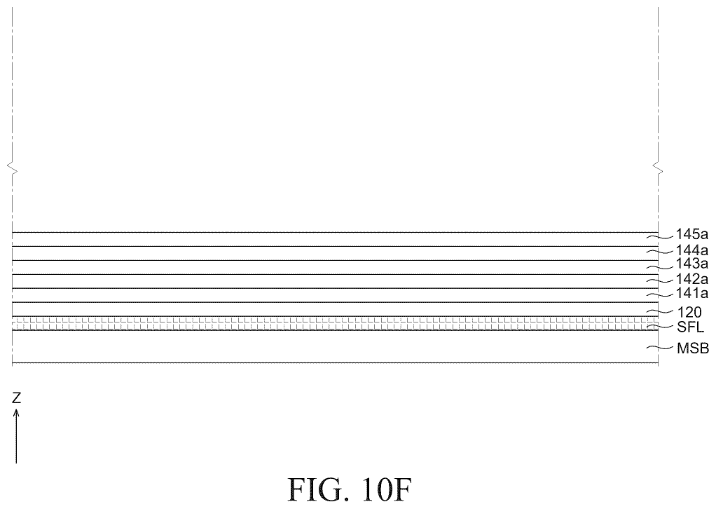

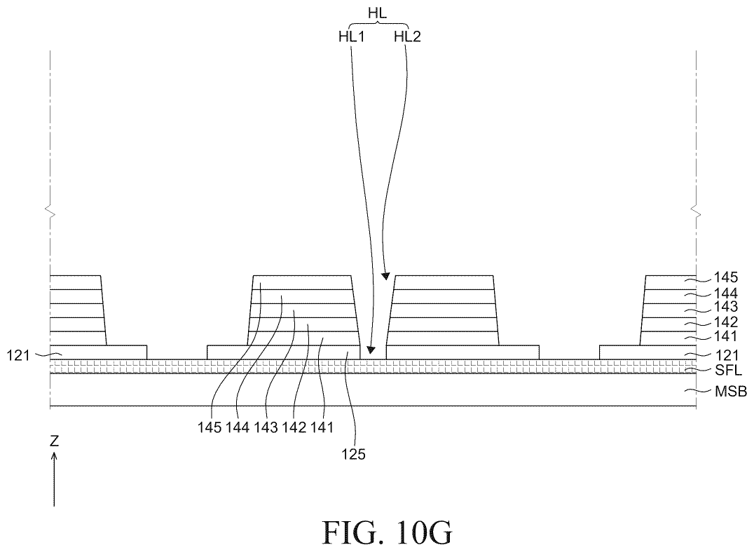

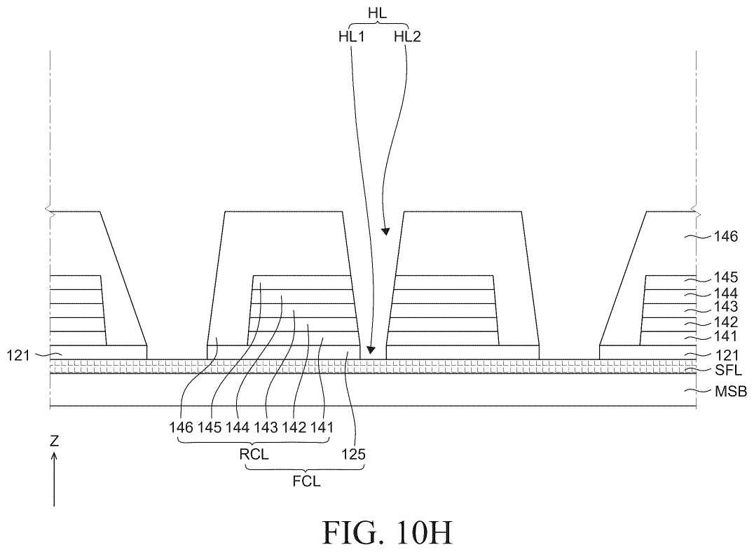

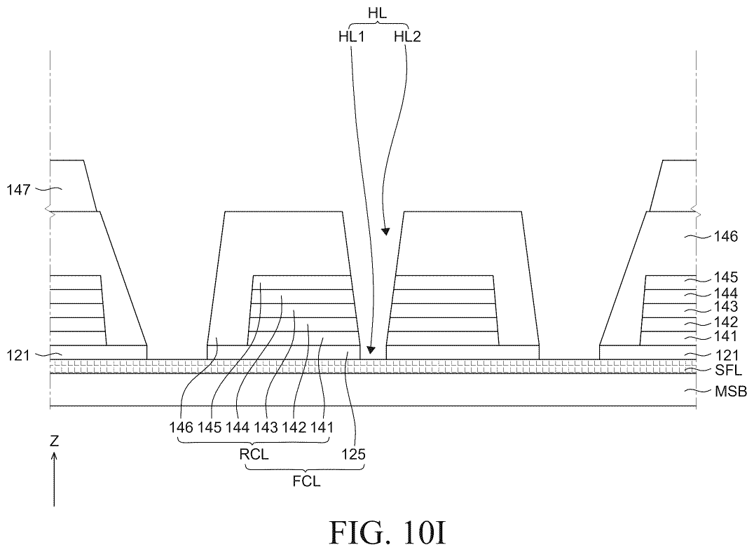

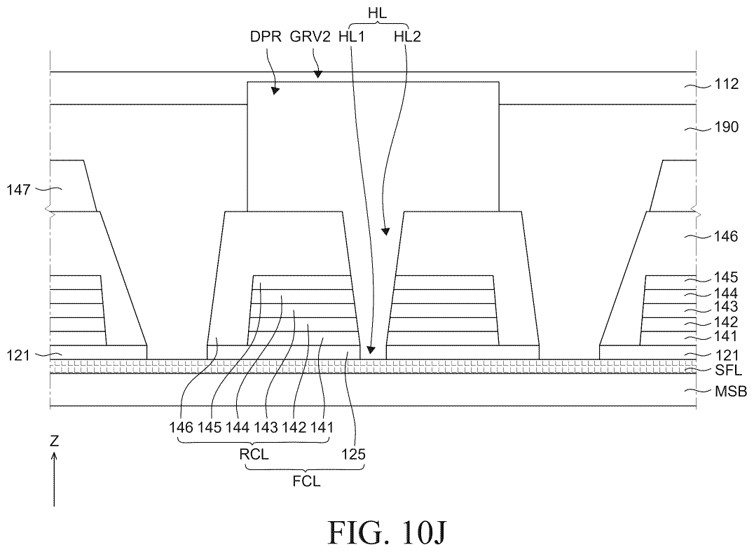

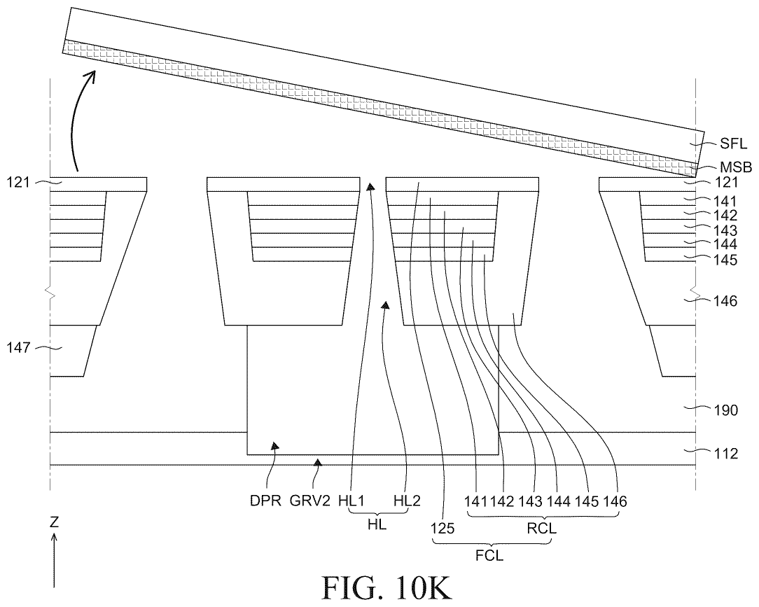

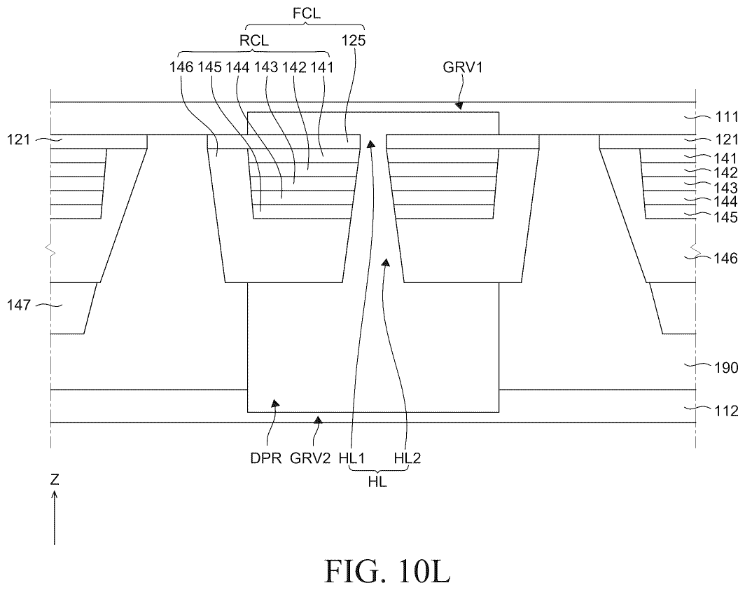

FIGS. 10A to 10L are process charts illustrating a manufacturing method of a display device according to exemplary embodiments of the present disclosure.

In the meantime, in FIGS. 10A to 10L, cross-sectional views according to the manufacturing process of the display device 100 according to the exemplary embodiment of the present disclosure which has been described with reference to FIGS. 5 and 6 are illustrated. For example, in FIGS. 10A to 10L, a manufacturing method of the display device 100 according to the exemplary embodiment of the present disclosure which has been described with reference to FIGS. 5 and 6 is sequentially illustrated. For the convenience of description, the description will be made based on the cross-sectional view of the display device 100 which has been described with reference to FIG. 6.

In the meantime, for the convenience of description, description which overlaps the description which has been made with reference to FIGS. 1 to 9C will not be repeated.

In the meantime, an insulating layer, a semiconductor layer, and a metal layer which will be described with reference to FIGS. 10A to 10L are formed by a manufacturing conventional process of a circuit element which forms the insulating layer, the semiconductor layer, and the metal layer by a coating or deposition method and selectively patterns the insulating layer, the semiconductor layer, and the metal layer by photolithography and an etching process to form various electrodes, various patterns, and signal lines. Therefore, for the convenience of description, a detailed description thereof will be omitted.

First, referring to FIG. 10A, a sacrificial layer SFL may be formed on a mother board MSB.

The mother board MSB is a substrate which supports components disposed on the lower substrate 111 during the process of manufacturing the display device 100. The mother board MSB may be formed of a material having a rigidity. For example, the mother board MSB may be formed of glass, but is not limited thereto.

The mother board MSB may be used to simultaneously manufacture a plurality of display devices 100. For example, a plurality of cells is defined on the mother board MSB and each cell may correspond to each of the plurality of manufactured display devices.

The sacrificial layer SFL formed on the mother board MSB is a layer used to separate the pattern layer 120 of the display device 100 from the mother board MSB. The sacrificial layer SFL may be formed of a material in which when the laser is irradiated, an interfacial bonding force of the sacrificial layer SLF is decomposed to weaken the adhesive strength with the pattern layer 120 of the display device 100. For example, the sacrificial layer SFL may be configured by silicon nitride (SiNx) or silicon oxide (SiOx) or a laminated structure of silicon nitride and silicon oxide. The sacrificial layer SFL may be formed by depositing silicon nitride and silicon oxide on the entire surface of the mother board MSB, but is not limited thereto.

Thereafter, the pattern layer 120 may be provided on the sacrificial layer SFL and first to fifth insulating materials 141a to 145a may be provided on the pattern layer 120.

To be more specific, first, further referring to FIG. 10B, a first insulating material 141a may be provided on the pattern layer 120. The first insulating material 141a may be a material for forming the buffer layer 141 which has been described with reference to FIGS. 5 and 6.

In the meantime, even though it is not separately illustrated, a semiconductor layer for configuring the active layers 152 and 162 is provided (for example, deposited) on the first insulating material 141a and at least a part of the semiconductor layer is patterned to form the active layers 152 and 162.

Next, further referring to FIG. 10C, a second insulating material 142a may be provided on the first insulating material 141a. The second insulating material 142a may be a material for forming the gate insulating layer 142 which has been described with reference to FIGS. 5 and 6.

In the meantime, even though it is not separately illustrated, a first metal layer for configuring the gate electrodes 151 and 161 is provided (for example, deposited) on the second insulating material 142a and at least a part of the first metal layer is patterned to form the gate electrodes 151 and 161.

Next, further referring to FIG. 10D, a third insulating material 143a may be provided on the second insulating material 142a. The third insulating material 143a may be a material for forming the first interlayer insulating layer 143 which has been described with reference to FIGS. 5 and 6.

In the meantime, even though it is not separately illustrated, a second metal layer for configuring the intermediate metal layer IM is provided (for example, deposited) on the third insulating material 143a and at least a part of the second metal layer is patterned to form the intermediate metal layer IM.

Next, further referring to FIG. 10E, a fourth insulating material 144a may be provided on the third insulating material 143a. The fourth insulating material 144a may be a material for forming the second interlayer insulating layer 144 which has been described with reference to FIGS. 5 and 6.

In the meantime, even though it is not separately illustrated, a third metal layer for configuring the plurality of pads DP and VP, the source electrode 153, and the drain electrodes 154 and 164 is provided (for example, deposited) on the fourth insulating material 144a. At least a part of the third metal layer is patterned to form the plurality of pads DP and VP, the source electrode 153, and the drain electrodes 154 and 164.

Next, further referring to FIG. 10F, a fifth insulating material 145a may be provided on the fourth insulating material 144a. The fifth insulating material 145a may be an insulating material for forming the passivation layer 145 which has been described with reference to FIGS. 5 and 6.

Next, further referring to FIG. 10G, at least a part of a fifth insulating material 145a, a fourth insulating material 144a, a third insulating material 143a, a second insulating material 142a, and a first insulating material 141a is removed (for example, etched) using at least one mask. By doing this, a passivation layer 145 (or a fifth insulating layer), a second interlayer insulating layer 144 (or a fourth insulating layer), a first interlayer insulating layer 143 (for example, a third insulating layer), a gate insulating layer 142 (or a second insulating layer), and a buffer layer 141 (or a first insulating layer) may be formed. For example, among the fifth insulating material 145a, the fourth insulating material 144a, the third insulating material 143a, the second insulating material 142a, and the first insulating material 141a, the fifth insulating material 145a, the fourth insulating material 144a, the third insulating material 143a, the second insulating material 142a, and the first insulating material 141a which are disposed in a remaining area excluding an area in which the plurality of first plate patterns 121 and the plurality of first auxiliary patterns 125 of the pattern layer 120 are formed are removed. By doing this, the passivation layer 145 (or the fifth insulating layer), the second interlayer insulating layer 144 (or the fourth insulating layer), the first interlayer insulating layer 143 (or the third insulating layer), the gate insulating layer 142 (or the second insulating layer), and the buffer layer 141 (or the first insulating layer) may be formed.

To this end, a photo resist PR is coated on the fifth insulating material 145a, the fourth insulating material 144a, the third insulating material 143a, the second insulating material 142a, and the first insulating material 141a disposed in the remaining area excluding the area in which the plurality of first plate patterns 121 and the plurality of first auxiliary patterns 125 of the pattern layer 120 are formed. Thereafter, the passivation layer 145 (or the fifth insulating layer), the second interlayer insulating layer 144 (or the fourth insulating layer), the first interlayer insulating layer 143 (or the third insulating layer), the gate insulating layer 142 (or the second insulating layer), and the buffer layer 141 (or the first insulating layer) may be formed, respectively, using at least one mask having a mask opening which overlaps the remaining area.

Further, the fifth insulating material 145a, the fourth insulating material 144a, the third insulating material 143a, the second insulating material 142a, and the first insulating material 141a which are disposed in a partial area of an area in which the plurality of first auxiliary pattern 125 of the pattern layer 120 is formed, among the fifth insulating material 145a, the fourth insulating material 144a, the third insulating material 143a, the second insulating material 142a, and the first insulating material 141a, are removed to form the second through-hole HL2.

According to the exemplary embodiment, the passivation layer 145, the second interlayer insulating layer 144, the first interlayer insulating layer 143, the gate insulating layer 142, and the buffer layer 141 are etched according to a soft etching condition. Therefore, a side surface of each of the passivation layer 145, the second interlayer insulating layer 144, the first interlayer insulating layer 143, the gate insulating layer 142, and the buffer layer 141 has an overall oblique tapered structure.

Further, the plurality of first plate patterns 121 and the plurality of auxiliary patterns 125 may be formed by removing (for example, etching) at least a part of the pattern layer 120 using at least one mask. To this end, after coating the photo resist PR on at least a partial area of the pattern layer 120, the plurality of first plate patterns 121 and the plurality of first auxiliary patterns 125 may be formed using at least one mask having a mask opening which overlaps the corresponding area.

Further, a partial area of the area in which the plurality of first auxiliary patterns 125 of the pattern layer 120 is formed is removed to form the first through-hole HL1. In one exemplary embodiment, the first through-hole HL1 may overlap the second through-hole HL2.

Next, further referring to FIG. 10H, the planarization layer 146 may be provided on the passivation layer 145. For example, the planarization layer 146 is by patterning formed after forming an insulating material for configuring the planarization layer on the passivation layer 145. For example, the planarization layer 146 may be patterned so as to be provided in an area in which the plurality of first plate patterns 121 and the plurality of first auxiliary patterns 125 are formed.

The planarization layer 146 is provided so as to cover top surfaces and side surfaces of the buffer layer 141, the gate insulating layer 142, the first interlayer insulating layer 143, the second interlayer insulating layer 144, and the passivation layer 145 and may be provided so as to cover at least a part of a top surface of the first plate pattern 121 and a top surface of the first auxiliary pattern 125.

Further, the planarization layer 146 is provided in an area in which the plurality of first auxiliary patterns 125 is formed so that the planarization layer 146 may not be formed in an area in which the first through-hole HL1 and the second through-hole HL2 are disposed.

Next, further referring to FIG. 10I, a bank 147 may be provided on the planarization layer 146. The bank 147 may be disposed so as to cover at least a part of the connection lines 181 and 182 and the planarization layer 146.

Next, further referring to FIG. 10J, the upper substrate 112 may be provided. The upper substrate 112 may be provided so as to cover various components disposed on the lower substrate 111, for example, the pattern layer 120, the buffer layer 141, the gate insulating layer 142, the first interlayer insulating layer 143, the second interlayer insulating layer 144, the passivation layer 145, the planarization layer 146, and the bank 147. For example, the upper substrate 112 may be bonded by a filling layer 190.

Further, as described above, the upper substrate 112 may include the plurality of second grooves GRV2 formed by removing at least a part of the upper substrate 112. Each of the plurality of second grooves GRV2 may be disposed so as to overlap the first through-hole HL1 of the first auxiliary pattern 125 and/or the second through-hole HL2 of the reinforcement layer RCL provided on the first auxiliary pattern 125.

Further, the internal empty space, that is, the damper DPR is formed by the second groove GRV2, the first through-hole HL1, and the second through-hole HL2 and the damper DPR may be filled with gas, for example, air. That is, the filling layer 190 is not provided in an area in which the damper DPR is formed.

According to the exemplary embodiment, the filling layer 190 which is patterned so as to correspond to a shape of the second groove GRV2 may be attached onto one surface of the upper substrate 112 including the plurality of second grooves GRV2. For example, the filling layer 190 may be patterned so as not to be formed in an area in which the second groove GRV2 (or the damper DPR) is disposed. For example, the filling layer 190 is patterned by a printing technique (for example, Gravure offset, screen printing, or inkjet printing) and is hardened by thermal hardening or UV hardening to be bonded to the upper substrate 112.

Next, further referring to FIG. 10K, a laser lift off (LLO) process may be performed to separate the sacrificial layer SFL and the mother board MSB from the pattern layer 120 of the display device 100.

Next, further referring to FIG. 10L, the lower substrate 111 is provided to manufacture the display device 100. Further, as described above, the lower substrate 111 may include the plurality of first grooves GRV1 formed by removing at least a part of the lower substrate 111. Each of the plurality of first grooves GRV1 may be disposed so as to overlap the first through-hole HL1 of the first auxiliary pattern 125 and/or the second through-hole HL2 of the reinforcement layer RCL provided on the first auxiliary pattern 125.

Further, the internal empty space, that is, the damper DPR may be formed by the first groove GRV1, the first through-hole HL1, and the second through-hole HL2 together with the second groove GRV2.

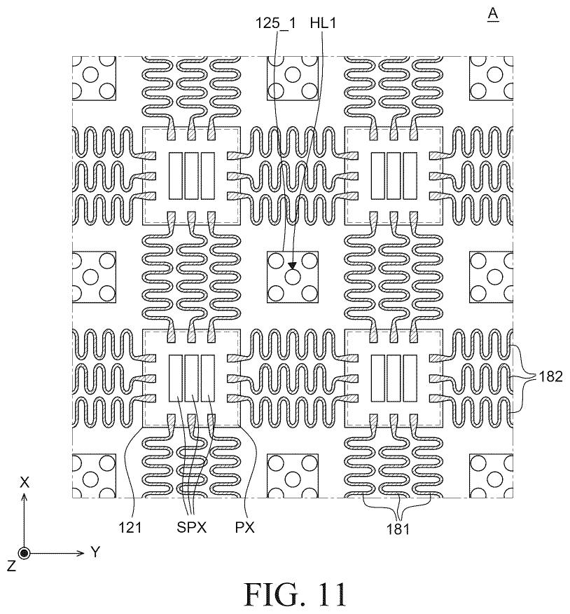

FIG. 11 is an enlarged plan view illustrating another example of a part A of FIG. 2 according to one embodiment.

In the meantime, FIG. 11 illustrates a modified embodiment of FIG. 4 with regard to the number of first through-holes HL1 formed in one first auxiliary pattern 125_1. Accordingly, for the convenience of description, a redundant description will not be repeated.

Referring to FIG. 11, a plurality of first auxiliary patterns 125_1 may be disposed on the active area AA of the lower substrate 111. The plurality of first auxiliary patterns 125_1 is spaced apart from each other to be disposed on the lower substrate 111.

In one exemplary embodiment, each of the plurality of first auxiliary patterns 125_1 may include a plurality of first through-holes HL1. For example, at least a part of each of the plurality of first auxiliary patterns 125 is removed to form a plurality of first through-holes HL1.

According to the exemplary embodiment, plurality of first through-holes HL1 formed in each of the plurality of first auxiliary patterns 125_1 may be formed in the center portion and each corner portion of the first auxiliary pattern 125_1. For example, one first auxiliary pattern 125_1 may include five first through-holes HL1. As described above, a degree of controlling the flow rate of air is changed by the first through-hole HL1 of the damper DPR according to the number of first through-holes HL1 formed in the first auxiliary pattern 125_1. Accordingly, the number of first through-holes HL1 formed in each of the plurality of first auxiliary patterns 125_1 may be determined according to the design of the display device 100.

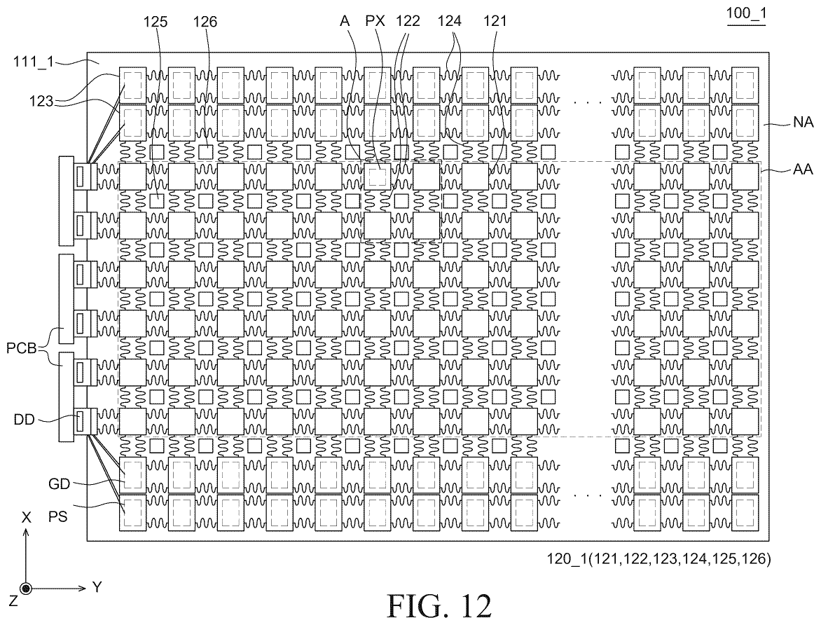

FIG. 12 is a plan view illustrating a display device according to exemplary embodiments of the present disclosure.

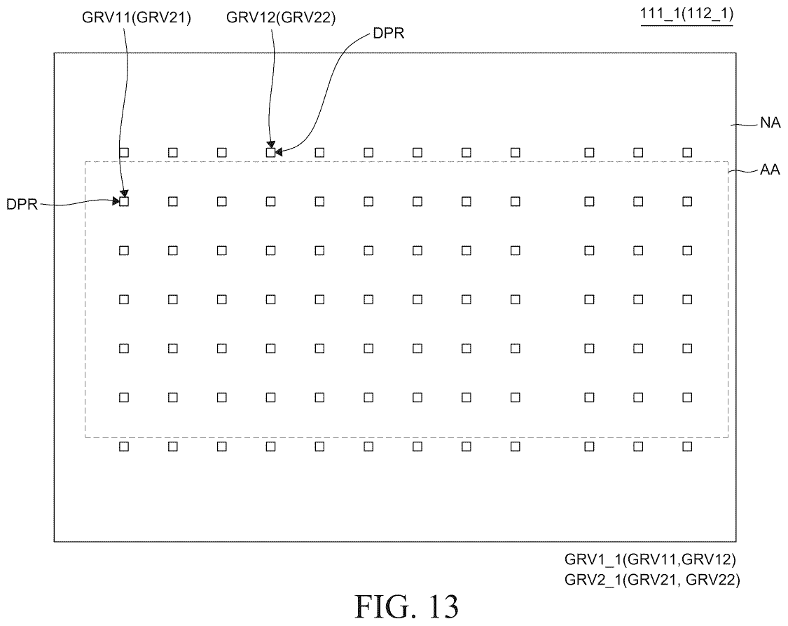

FIG. 13 is a plan view illustrating an example of a lower substrate and an upper substrate included in a display device of FIG. 12.

FIGS. 12 and 13 illustrate a modified embodiment of FIGS. 2 and 3, with regard to a pattern layer 120_1 included in the display device 100_1 and an area in which a first groove GRV1_1 and a second groove GRV2_1 formed in each of a lower substrate 111_1 and an upper substrate 112_1 are disposed. Accordingly, for the convenience of description, a redundant description will not be repeated.

Referring to FIGS. 12 and 13, a display device 100_1 according to exemplary embodiments of the present disclosure may include a lower substrate 111_1, an upper substrate 112_1, a pattern layer 120_1, a plurality of pixels PX, a gate driver GD, a data driver DD, and a power supply PS.

The pattern layer 120_1 may include a plurality of first plate patterns 121 and a plurality of first line patterns 122 disposed in the active area AA and a plurality of second plate patterns 123 and a plurality of second line patterns 124 disposed in the non-active area NA.

Further, in the exemplary embodiment, the pattern layer 120_1 may further include a plurality of first auxiliary patterns 125 disposed in the active area AA and a plurality of second auxiliary patterns 126 disposed in the non-active area NA.

The plurality of second auxiliary patterns 126 may be disposed in the form of islands which are spaced apart from each other. The plurality of second auxiliary patterns 126 may be individually separated.

Further, in FIG. 12, it is illustrated that the plurality of second auxiliary patterns 126 has a quadrangular shape, but is not limited thereto and the plurality of second auxiliary patterns 126 is modified in various forms.

In one exemplary embodiment, each of the plurality of second auxiliary patterns 126 is disposed to be adjacent to the plurality of second plate patterns 123 in a direction different from the first direction X and the second direction Y. For example, each of the plurality of second auxiliary patterns 126 may be disposed to be adjacent to the plurality of second plate patterns 126 in a diagonal direction (for example, a third direction) between the first direction X and the second direction Y. Therefore, as illustrated in FIG. 12, each of the plurality of second auxiliary patterns 126 may be disposed between the second line patterns 124 which are adjacent in the first direction X and/or between the second line patterns 124 which are adjacent in the second direction Y.

Further, as illustrated in FIG. 12, the plurality of second auxiliary patterns 126 are not connected to the line pattern, for example, the first line pattern 122 and the second line pattern 124, but may be disposed to be spaced apart from each other, unlike the first plate pattern 121 and the second plate pattern 123.

Further referring to FIG. 13, a groove may be formed in each of the lower substrate 111_1 and the upper substrate 112_1. For example, the lower substrate 111_1 includes a plurality of first grooves GRV1_1 formed on a planar surface (for example, a top surface) opposite to the upper substrate 112_1 and the upper substrate 112_1 may include a plurality of second grooves GRV2_1 formed on a planar surface (for example, a bottom surface) opposite to the lower substrate 111_1.

In one exemplary embodiment, the plurality of first grooves GRV1_1 defined on the lower substrate 111_1 may include a plurality of first sub grooves GRV11 formed in the active area AA and a plurality of second sub grooves GRV12 formed in the non-active area NA. Further, the plurality of second grooves GRV2_1 defined on the upper substrate 112_1 may include a plurality of third sub grooves GRV21 formed in the active area AA and a plurality of fourth sub grooves GRV22 formed in the non-active area NA.

In one exemplary embodiment, each of the plurality of first grooves GRV1_1 defined on the lower substrate 111_1 may overlap each of the plurality of second grooves GRV2_1 defined on the upper substrate 112. For example, the plurality of first sub grooves GRV11 which are defined on the lower substrate 111_1 and is disposed in the active area AA and the plurality of third sub grooves GRV21 which is defined on the upper substrate 112_1 and is disposed in the active area AA may be formed in the same position on the planar surface. Similarly, the plurality of second sub grooves GRV12 which are defined on the lower substrate 111_1 and are disposed in the non-active area NA and the plurality of fourth sub grooves GRV22 which are defined on the upper substrate 112_1 and are disposed in the non-active area NA are formed in the same position on the planar surface.

Each of the plurality of first sub grooves GRV11 and the plurality of third sub grooves GRV21 may be disposed so as to overlap the plurality of first auxiliary patterns 125 included in the pattern layer 120_1. That is, each of the plurality of first sub grooves GRV11 and the plurality of third sub grooves GRV21 may be disposed so as not to overlap the plurality of first plate patterns 121 and the plurality of first line patterns 122 included in the pattern layer 120_1. Accordingly, the damper DPR defined by the first sub groove GRV11 and the third sub groove GRV21 may be formed so as to overlap the plurality of first auxiliary patterns 125.

Further, each of the plurality of second sub grooves GRV12 and the plurality of fourth sub grooves GRV22 may be disposed so as to overlap the plurality of second auxiliary patterns 126 included in the pattern layer 120_1. That is, each of the plurality of second sub grooves GRV12 and the plurality of fourth sub grooves GRV22 may be disposed so as not to overlap the plurality of second plate patterns 123 and the plurality of second line patterns 124 included in the pattern layer 120_1. Accordingly, the damper DPR defined by the second sub groove GRV12 and the fourth sub groove GRV22 may be formed so as to overlap the plurality of second auxiliary patterns 126.

As described above, the damper DPR which controls the air flow rate at the time of the external shocks is formed in the internal empty space, not only in the active area AA, but also in the non-active area NA. Accordingly, the shock resistance of the display device 100_1 may be enhanced and thus the stretching reliability of the display device 100_1 may be improved.

As described above, the display device according to the exemplary embodiments of the present disclosure may include a damper (or an internal empty space) formed by the first groove defined on the lower substrate, the second groove defined on the upper substrate, and the through-hole defined on the display panel. In this case, when a force (or a shock) is applied to the display device from the outside, the force (or the shock) applied from the outside is not directly transmitted to the display panel, but may be dispersed by gas (for example, air) in the damper.

Accordingly, the shock resistance of the display device may be improved and damage of various components included in the display device, for example, a connection line, caused by the external shock may be suppressed. Therefore, the stretching reliability of the display device may be improved.

The exemplary embodiments of the present disclosure can also be described as follows:

According to an aspect of the present disclosure, a display device may include a stretchable lower substrate a plurality of plate patterns which are disposed on the lower substrate to be spaced apart from each other a plurality of line patterns which are disposed between plate patterns adjacent in a first direction, among the plurality of plate patterns and between plate patterns adjacent in a second direction different from the first direction, among the plurality of plate patterns, on the lower substrate a plurality of connection lines which are disposed above each of the plurality of line patterns and a plurality of auxiliary patterns which are adjacent to the plurality of plate patterns in a diagonal direction between the first direction and the second direction, on the lower substrate.

Each of the plurality of auxiliary patterns may be disposed between the plurality of line patterns.

Each of the plurality of line patterns may be disposed between adjacent plate patterns, among the plurality of plate patterns, to connect the adjacent plate patterns and the plurality of auxiliary patterns and the plurality of line patterns may be disposed to be spaced apart from each other without being connected.

Each of the plurality of auxiliary patterns may include at least one first through-hole.

The display device may further include a reinforcement layer which includes at least one insulating layer and is disposed above each of the plurality of auxiliary patterns.

The reinforcement layer may include a second through-hole which overlaps the at least one first through-hole.

A first groove which may overlap the first through-hole is defined on the lower substrate.

A width of the first groove may be larger than a width of the first through-hole.

The display device may further include a stretchable upper substrate which is opposite to the lower substrate. A second groove which overlaps the first through-hole may be defined on the upper substrate.

A width of the second groove may be larger than a width of the first through-hole.

According to an embodiment of the present disclosure, a display device includes a stretchable lower substrate a plurality of plate patterns which are disposed on the lower substrate to be spaced apart from each other a plurality of line patterns which are disposed between plate patterns adjacent in a first direction, among the plurality of plate patterns and between plate patterns adjacent in a second direction different from the first direction, among the plurality of plate patterns, on the lower substrate; and a plurality of connection lines which are disposed above each of the plurality of line patterns, and a first groove which does not overlap the plurality of plate patterns and the plurality of line patterns are defined on the lower substrate.

The first groove may be disposed to be adjacent to the plurality of plate patterns in a diagonal direction between the first direction and the second direction.

The display device may further include a plurality of auxiliary patterns which are disposed so as to overlap the first groove, on the lower substrate.

Each of the plurality of auxiliary patterns may include at least one first through-hole.

The display device may further include a reinforcement layer which includes at least one insulating layer and is disposed above each of the plurality of auxiliary patterns.

The reinforcement layer may include a second through-hole which overlaps the at least one first through-hole.

The display device may further include a stretchable upper substrate which is opposite to the lower substrate. A second groove which overlaps the first groove may be defined on the upper substrate.

According to an embodiment of the present disclosure, a display device may include a stretchable lower substrate on which a first groove is defined; a stretchable upper substrate which is opposite to the lower substrate and defines a second groove overlapping the first groove; and a display panel disposed between the lower substrate and the upper substrate.

The display panel may include a through-hole which overlaps the first groove and the second groove.

An internal empty space formed by the first groove, the second groove, and the through-hole may be filled with gas.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope of the present disclosure thereof should be construed as falling within the scope of the present disclosure.

What is claimed is:

1. A display device comprising:
a stretchable lower substrate;
a plurality of plate patterns on the stretchable lower substrate and spaced apart from each other;
a plurality of line patterns on the stretchable lower substrate, the plurality of line patterns between plate patterns from the plurality of plate patterns that are adjacent in a first direction and between plate patterns from the plurality of plate patterns that are adjacent in a second direction that is different from the first direction;
a plurality of connection lines disposed above each of the plurality of line patterns; and
a plurality of auxiliary patterns on the stretchable lower substrate, the plurality of auxiliary patterns adjacent to the plurality of plate patterns in a diagonal direction between the first direction and the second direction.

2. The display device according to claim 1, wherein each of the plurality of auxiliary patterns is between the plurality of line patterns.

3. The display device according to claim 1, wherein each of the plurality of line patterns is between adjacent plate patterns from the plurality of plate patterns and connect the adjacent plate patterns and the plurality of auxiliary patterns, and the plurality of line patterns are spaced apart from each other without being connected.

4. The display device according to claim 1, wherein each of the plurality of auxiliary patterns includes at least one first through-hole.

5. The display device according to claim 4, further comprising:
a reinforcement layer that includes at least one insulating layer and is disposed above each of the plurality of auxiliary patterns.

6. The display device according to claim 5, wherein the reinforcement layer includes a second through-hole which overlaps the at least one first through-hole.

7. The display device according to claim 4, wherein a first groove which overlaps the at least one first through-hole is defined on the stretchable lower substrate.

8. The display device according to claim 7, wherein a width of the first groove is larger than a width of the at least one first through-hole.

9. The display device according to claim 4, further comprising:
a stretchable upper substrate which is opposite to the stretchable lower substrate,
wherein a second groove that overlaps the at least one first through-hole is defined on the stretchable upper substrate.

10. The display device according to claim 9, wherein a width of the second groove is larger than a width of the at least one first through-hole.

11. A display device comprising:
a stretchable lower substrate;
a plurality of plate patterns on the stretchable lower substrate and spaced apart from each other;
a plurality of line patterns on the stretchable lower substrate, the plurality of line patterns between plate patterns from the plurality of plate patterns that are adjacent in a first direction and between plate patterns from the plurality of plate patterns that are adjacent in a second direction that is different from the first direction; and
a plurality of connection lines disposed above each of the plurality of line patterns,
wherein a first groove that is non-overlapping with the plurality of plate patterns and the plurality of line patterns is defined on the stretchable lower substrate.

12. The display device according to claim 11, wherein the first groove is adjacent to the plurality of plate patterns in a diagonal direction between the first direction and the second direction.

13. The display device according to claim 11, further comprising:
a plurality of auxiliary patterns on the stretchable lower substrate, the plurality of auxiliary patterns overlapping the first groove.

14. The display device according to claim 13, wherein each of the plurality of auxiliary patterns includes at least one first through-hole.

15. The display device according to claim 14, further comprising:
a reinforcement layer that includes at least one insulating layer and is disposed above each of the plurality of auxiliary patterns.

16. The display device according to claim 15, wherein the reinforcement layer includes a second through-hole that overlaps the at least one first through-hole.

17. The display device according to claim 11, further comprising:
a stretchable upper substrate which is opposite to the stretchable lower substrate, wherein a second groove that overlaps the first groove is defined on the stretchable upper substrate.

18. A display device comprising:
a stretchable lower substrate on which a first groove is defined;
a stretchable upper substrate which is opposite to the stretchable lower substrate and defines a second groove overlapping the first groove; and
a display panel between the stretchable lower substrate and the stretchable upper substrate.

19. The display device according to claim 18, wherein the display panel includes a through-hole that overlaps the first groove and the second groove.

20. The display device according to claim 19, wherein an internal empty space defined by the first groove, the second groove, and the through-hole is filled with gas.

21. The display device according to claim 18, further comprising:
a plurality of plate patterns on the stretchable lower substrate and spaced apart from each other; and
a plurality of line patterns on the stretchable lower substrate, the plurality of line patterns between plate patterns from the plurality of plate patterns that are adjacent in a first direction and between plate patterns from the plurality of plate patterns that are adjacent in a second direction that is different from the first direction.
